(19) United States
(12) Patent Application Publication
(10) Pub. No.: US 2016/0254315 A1
(43) Pub. Date: Sep. 1, 2016

(54) SEMICONDUCTOR DEVICE, LED HEAD, AND IMAGE FORMING APPARATUS

(71) Applicant: OKI DATA CORPORATION, TOKYO (JP)

(72) Inventors: HIRONORI FURUTA, GUNMA (JP); GENICHIRO MATSUO, GUNMA (JP)

(73) Assignee: OKI DATA CORPORATION, TOKYO (JP)

(21) Appl. No.: 15/007,153

(22) Filed: Jan. 26, 2016

(30) Foreign Application Priority Data
Feb. 27, 2015 (JP) 2015-038478
Mar. 31, 2015 (JP) 2015-072156

(51) Int. Cl. H01L 27/15; H01L 33/44; H01L 33/62

(52) U.S. Cl. CPC H01L 27/153; H01L 33/62; H01L 33/44

(57) ABSTRACT

Provided is a semiconductor device that includes a substrate, a plurality of light-emitting elements, an insulating film, and a wiring line. The light-emitting elements are disposed linearly at a predetermined interval on the substrate. The insulating film is provided on the substrate and has openings that correspond to the respective light-emitting element. The wiring line is provided on the insulating film and coupled to each of the light-emitting elements. The insulating film has an end. The end is provided in an array direction of the light-emitting elements and has a first cliff. The first cliff has a face that makes one of a right angle and an acute angle to a surface of the substrate.

### CROSS REFERENCE TO RELATED APPLICATIONS

This application claims the benefit of Japanese Priority Patent Application JP2015-038478 filed on Feb. 27, 2015 and Japanese Priority Patent Application JP2015-072156 filed on Mar. 31, 2015, the entire contents of each of which are incorporated herein by reference.

### BACKGROUND

The invention relates to a semiconductor device that includes light-emitting elements, and to an LED head and an image forming apparatus each including the semiconductor device.

An exposure unit directed to electrophotographic printing may employ an LED array head in which a number of light-emitting diodes (LEDs) are arrayed. The LED array head has a configuration in which a plurality of LED array chips, each having an array of LEDs, are further arranged. The LED array chip includes an organic insulating film, which may be made of polyimide without limitation, as an insulating film that serves to prevent an occurrence of short circuit. For reference, see page 4 and FIG. 2 of Japanese Unexamined Patent Application Publication No. 2002-289919. In particular, for a mesa LED array that involves a large step height, an organic insulating film is used that has a property of reducing steps to prevent disconnection of a wiring line. A patterning process by means of a photolithography without limitation is performed in a region where presence of the organic insulating film can be an obstacle, including a dicing line and a region in which a semiconductor and a wiring line come into contact with each other.

To prevent an occurrence of light reflection near a connection wiring line in the LED array chip, a method has been proposed in which a light-shielding film is formed between a light-emitting section and the connection wiring line to prevent light emitted from the light-emitting section from reaching the connection wiring line. For reference, see page 7 and FIG. 2 of Japanese Unexamined Patent Application Publication No. 2007-294725.

### SUMMARY

Applicants have found that a difference in index of refraction is generated between an organic insulating film (or a light-shielding film) and air, allowing light emitted from an LED to be transmitted through the organic insulating film as a waveguide. This causes the light to be leaked in a region different from a region where the LED emitting light is provided, especially at an end of a pattern of the organic insulating film, resulting in a reduction in quality of printing in a printer.

A semiconductor device according to an embodiment of the invention includes: a substrate; a plurality of light-emitting elements disposed linearly at a predetermined interval on the substrate; an insulating film provided on the substrate and having openings that correspond to the respective light-emitting elements, in which the insulating film has an end, the end is provided in an array direction of the light-emitting elements and has a first cliff, and the first cliff has a face that makes one of a right angle and an acute angle to a surface of the substrate; and a wiring line provided on the insulating film and coupled to each of the light-emitting elements.

A semiconductor device according to another embodiment of the invention includes: a substrate; a plurality of light-emitting elements disposed on the substrate; an insulating film provided in a region on the substrate and having openings that face the respective light-emitting elements, in which the insulating film has an end that extends in an array direction of the light-emitting elements, and the region includes the light-emitting elements; and a light-shielding film that extends to cover the end of the insulating film.

Embodiments of the invention each therefore make it possible to prevent light from being leaked, at an end of a pattern of the insulating film, in a direction that influences exposure in a printing process.

It is to be understood that both the foregoing general description and the following detailed description are exemplary, and are intended to provide further explanation of the invention as claimed. Also, effects of the invention are not limited to those described above. Effects achieved by the invention may be those that are different from the above-described effects, or may include other effects in addition to those described above.

### BRIEF DESCRIPTION OF THE DRAWINGS

FIG. 1 is a schematic plan view of a main configuration of a semiconductor device according to a first example embodiment of the invention.

FIG. 2 is a schematic cross-sectional view, taken along line A-A of FIG. 1, of the semiconductor device illustrated in FIG. 1.

FIG. 3 is a schematic cross-sectional view, taken along line B-B of FIG. 1, of the semiconductor device illustrated in FIG. 1.

FIG. 4A is a cross-sectional view of a main part in a production step of an example manufacturing process of the semiconductor device illustrated in FIG. 1.

FIG. 4B is a cross-sectional view of the main part in a production step subsequent to that illustrated in FIG. 4A.

FIG. 4C is a cross-sectional view of the main part in a production step subsequent to that illustrated in FIG. 4B.

FIG. 4D is a cross-sectional view of the main part in a production step subsequent to that illustrated in FIG. 4C.

FIG. 5 is a schematic plan view of a main configuration of a semiconductor device according to a second example embodiment of the invention.

FIG. 6 is a schematic cross-sectional view, taken along line A-A of FIG. 5, of the semiconductor device illustrated in FIG. 5.

FIG. 7 is a schematic cross-sectional view, taken along line B-B of FIG. 5, of the semiconductor device illustrated in FIG. 5.

FIG. 8 is a schematic plan view of a main configuration of a semiconductor device according to a third example embodiment of the invention.

FIG. 9 is a schematic cross-sectional view, taken along line A-A of FIG. 8, of the semiconductor device illustrated in FIG. 8.

FIG. 10 is a schematic cross-sectional view, taken along line B-B of FIG. 8, of the semiconductor device illustrated in FIG. 8.

FIG. 11 is a schematic plan view of a main configuration of a semiconductor device according to a fourth example embodiment of the invention.

FIG. 12 is a schematic cross-sectional view, taken along line A-A of FIG. 11, of the semiconductor device illustrated in FIG. 11.

FIG. 13 is a schematic cross-sectional view, taken along line B-B of FIG. 11, of the semiconductor device illustrated in FIG. 11.

FIG. 14A is a cross-sectional view of a main part in a production step of an example manufacturing process of the semiconductor device illustrated in FIG. 11.

FIG. 14B is a cross-sectional view of the main part in a production step subsequent to that illustrated in FIG. 14A.

FIG. 14C is a cross-sectional view of the main part in a production step subsequent to that illustrated in FIG. 14B.

FIG. 14D is a cross-sectional view of the main part in a production step subsequent to that illustrated in FIG. 14C.

FIG. 14E is a cross-sectional view of the main part in a production step subsequent to that illustrated in FIG. 14D.

FIG. 15 is a schematic plan view of a main configuration of a semiconductor device according to a fifth example embodiment of the invention.

FIG. 16 is a schematic cross-sectional view, taken along line A-B of FIG. 15, of the semiconductor device illustrated in FIG. 15.

FIG. 17 describes an operation of the semiconductor device illustrated in FIG. 15.

FIG. 18 is a schematic plan view of a main configuration of a semiconductor device according to a sixth example embodiment of the invention.

FIG. 19 is a schematic cross-sectional view, taken along line A-B of FIG. 18, of the semiconductor device illustrated in FIG. 18.

FIG. 20 is a schematic plan view of a main configuration of a semiconductor device according to a seventh example embodiment of the invention.

FIG. 21 is a schematic cross-sectional view, taken along line A-A of FIG. 20, of the semiconductor device illustrated in FIG. 20.

FIG. 22 is a schematic plan view of a main configuration of a semiconductor device according to an eighth example embodiment of the invention.

FIG. 23 is a schematic cross-sectional view, taken along line A-A of FIG. 22, of the semiconductor device illustrated in FIG. 22.

FIG. 24 is a schematic plan view of a main configuration of a semiconductor device according to a ninth example embodiment of the invention.

FIG. 25 is a schematic cross-sectional view, taken along line A-A of FIG. 24, of the semiconductor device illustrated in FIG. 24.

FIG. 26 is a schematic plan view of a main configuration of a semiconductor device according to a tenth example embodiment of the invention.

FIG. 27 is a schematic cross-sectional view, taken along line A-A of FIG. 26, of the semiconductor device illustrated in FIG. 26.

FIG. 28 is a schematic plan view of a main configuration of a semiconductor device according to an eleventh example embodiment of the invention.

FIG. 29 is a schematic cross-sectional view, taken along line A-B of FIG. 28, of the semiconductor device illustrated in FIG. 28.

FIG. 30 is a schematic cross-sectional view, taken along line C-D of FIG. 28, of the semiconductor device illustrated in FIG. 28.

FIG. 31 describes an operation of the semiconductor device illustrated in FIG. 28.

FIG. 32 is a schematic plan view of a main configuration of a semiconductor device according to a twelfth example embodiment of the invention.

FIG. 33 is a schematic cross-sectional view, taken along line E-F of FIG. 32, of the semiconductor device illustrated in FIG. 32.

FIG. 34 is a schematic cross-sectional view, taken along line G-H of FIG. 32, of the semiconductor device illustrated in FIG. 32.

FIG. 35 illustrates an LED print head according to an example embodiment of the invention.

FIG. 36 is a plan view of an arrangement according to an example configuration of an LED unit provided in the LED print head illustrated in FIG. 35.

FIG. 37 schematically illustrates a main configuration of an image forming apparatus according to an example embodiment of the invention.

### DETAILED DESCRIPTION

In the following, some example embodiments of the invention are described in detail with reference to the accompanying drawings. Note that the following description is directed to illustrative examples of the invention and not to be construed as limiting to the invention. Also, factors including, without limitation, arrangement, dimensions, and a dimensional ratio of elements illustrated in each drawing are illustrative only and not to be construed as limiting to the invention.

### First Example Embodiment

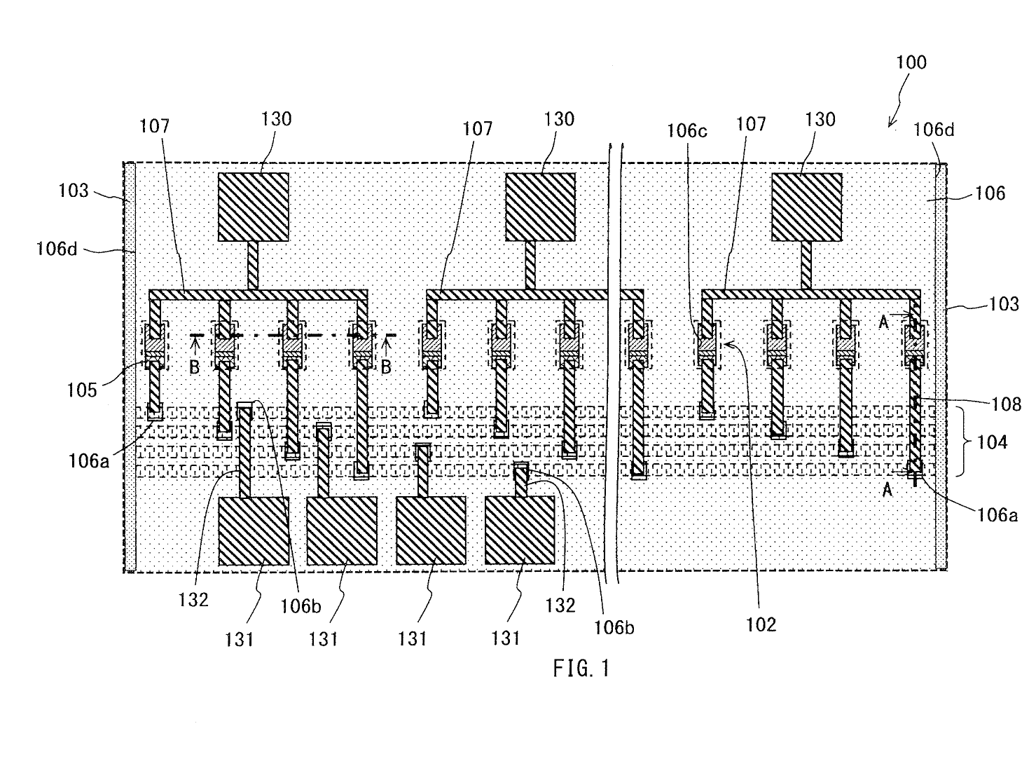

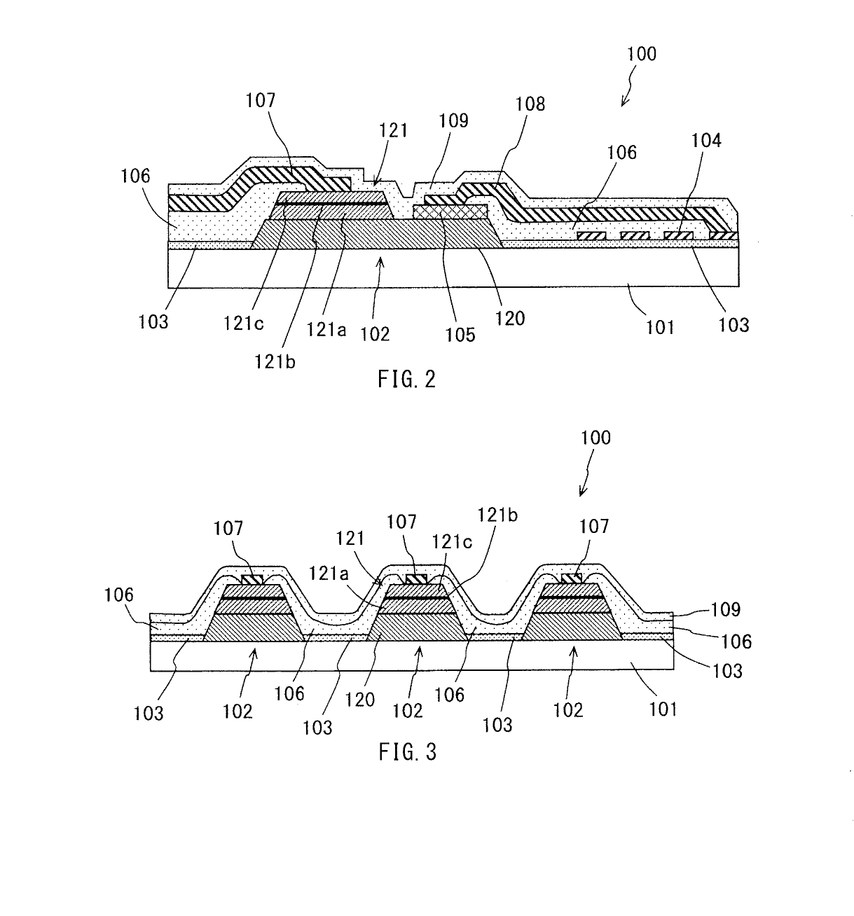

FIG. 1 is a schematic plan view of a main configuration of a semiconductor device 100 according to a first example embodiment of the invention. FIG. 2 is a schematic cross-sectional view, taken along line A-A of FIG. 1, of the semiconductor device 100 illustrated in FIG. 1. FIG. 3 is a schematic cross-sectional view, taken along line B-B of FIG. 1, of the semiconductor device 100 illustrated in FIG. 1. Note that a passivation film 109 and other elements to be described later are omitted in FIG. 1 for easier illustration.

Referring to FIG. 1, the semiconductor device 100 includes a plurality of LEDs 102 formed on a substrate 101 (see FIG. 2). The substrate 101 may have an elongated plate-like shape, and the LEDs 102 may be formed linearly at predetermined intervals on the substrate 101 in a longitudinal direction of the substrate 101. The LEDs 102 each may serve as a non-limiting example of a light-emitting element. The LEDs 102 formed on the substrate 101 each may have multiple layers. Referring to FIGS. 2 and 3, each of the LEDs 102 may have a cathode layer 120, and a light-emitting section 121 and a cathode electrode 105 both formed on the cathode layer 120. The light-emitting section 121 may have a formation in which an N-cladding layer 121a, an active layer 121b, and a P-cladding layer 121c are stacked in the order from the bottom.

The semiconductor device 100 may also include an underlayer insulating film 103 as illustrated in FIGS. 2 and 3 at a location excluding a region in which the LEDs 102 are formed. A region on the underlayer insulating film 103 may include on-substrate wiring lines 104 that may be formed in a side-by-side fashion in four lines along the LEDs 102 arrayed in the longitudinal direction of the substrate 101. Such LEDs 102 may be hereinafter referred to as “LED lines”.

The region on the underlayer insulating film 103 may also include a plurality of wire-bonding individual electrode pads 131 and a plurality of wire-bonding common electrode pads 130 as illustrated in FIG. 1. In this non-limiting embodiment, four individual electrode pads 131 may be formed adjacent to each other at a location on the side of the on-substrate wiring lines 104 opposite to the LED lines. The common electrode pads 130 may be formed at a location on the side of the LED lines opposite to the on-substrate wiring lines 104, and each may be disposed corresponding to a group of four LEDs 102.

The LEDs 102 are each electrically coupled to a common electrode wiring line 107 and an individual electrode wiring line 108 both serving as an non-limiting example of a “wiring line”. As an underlayer of the common electrode wiring line 107 and the individual electrode wiring lines 108, an organic insulating film 106 is formed. The organic insulating film 106 may cover steps formed by the cathode layer 120 and the light-emitting section 121 of each of the LEDs 102 as illustrated in cross-sectional FIGS. 2 and 3 to thereby reduce the steps. Also, to ensure insulation of the on-substrate wiring lines 104 from any other element such as the individual electrode wiring lines 108, the organic insulating film 106 may be formed in any region excluding: a predetermined location at a surface of each of the LEDs 102; surfaces of the individual electrode pads 131 and the common electrode pads 130; and a predetermined connection part to be described later.

Note that FIG. 1 denotes an outline of each of the LEDs 102 with a dotted line, and illustrates a configuration in which the organic insulating film 106 having openings 106c on the respective LEDs 102 cover outer edges of the respective LEDs 102.

The P-cladding layers 121c of the respective LEDs 102 may be electrically coupled to the common electrode wiring line 107 that may also serve as an anode electrode. The common electrode wiring line 107 may be formed on the organic insulating film 106 by which the steps are reduced as illustrated in FIG. 2, and may electrically couple the P-cladding layers 121c of the grouped, mutually-adjacent four LEDs 102 with corresponding one of the common electrode pads 130 as illustrated in FIG. 1.

The cathode electrodes 105 of the respective LEDs 102 may be electrically coupled to their respective individual electrode wiring lines 108. The individual electrode wiring lines 108 each may be formed on the organic insulating film 106 by which the steps are reduced and the individual electrode wiring lines 108 are insulated from the on-substrate wiring lines 104 as illustrated in FIG. 2. Also, as illustrated in FIG. 1, the individual electrode wiring lines 108 each may allow only the cathode electrode 105 of any LED 102 and its corresponding predetermined one of the on-substrate wiring lines 104 to be electrically coupled to each other through corresponding one of the openings 106a formed on the organic insulating film 106.

The four individual electrode pads 131 may be electrically coupled to their respective connection wiring lines 132. The connection wiring lines 132 may be formed on the organic insulating film 106, and each may be electrically coupled to only corresponding one of the on-substrate wiring lines 104 through corresponding one of the openings 106b formed on the organic insulating film 106.

A passivation film 109 as illustrated in FIGS. 2 and 3 may be formed on an upper surface of the semiconductor device 100 to prevent an occurrence of short circuit attributable to a factor such as, but not limited to, dust. The passivation film 109 may be formed in a region excluding the surfaces of the individual electrode pads 131 and the common electrode pads 130.

Also, on both ends of the semiconductor device 100 in an array direction (i.e., a longitudinal direction) of the LED lines, the organic insulating film 106 may be removed by a predetermined width throughout the entire region in a direction transverse to the longitudinal direction (i.e., a transverse direction), to expose the underlayer insulating film 103 as illustrated in FIG. 1. A cliff 106d may be formed on each end in the array direction (the longitudinal direction) of the organic insulating film 106. The cliff 106d may serve as a non-limiting example of a later-described first cliff.

With the example configuration described above, causing a current to flow from the anode electrode, e.g., the common electrode wiring line 107, to the cathode electrode 105 of any of the desired LEDs 102 allows the active layer 121b of the light-emitting section 121 thereof to emit light.

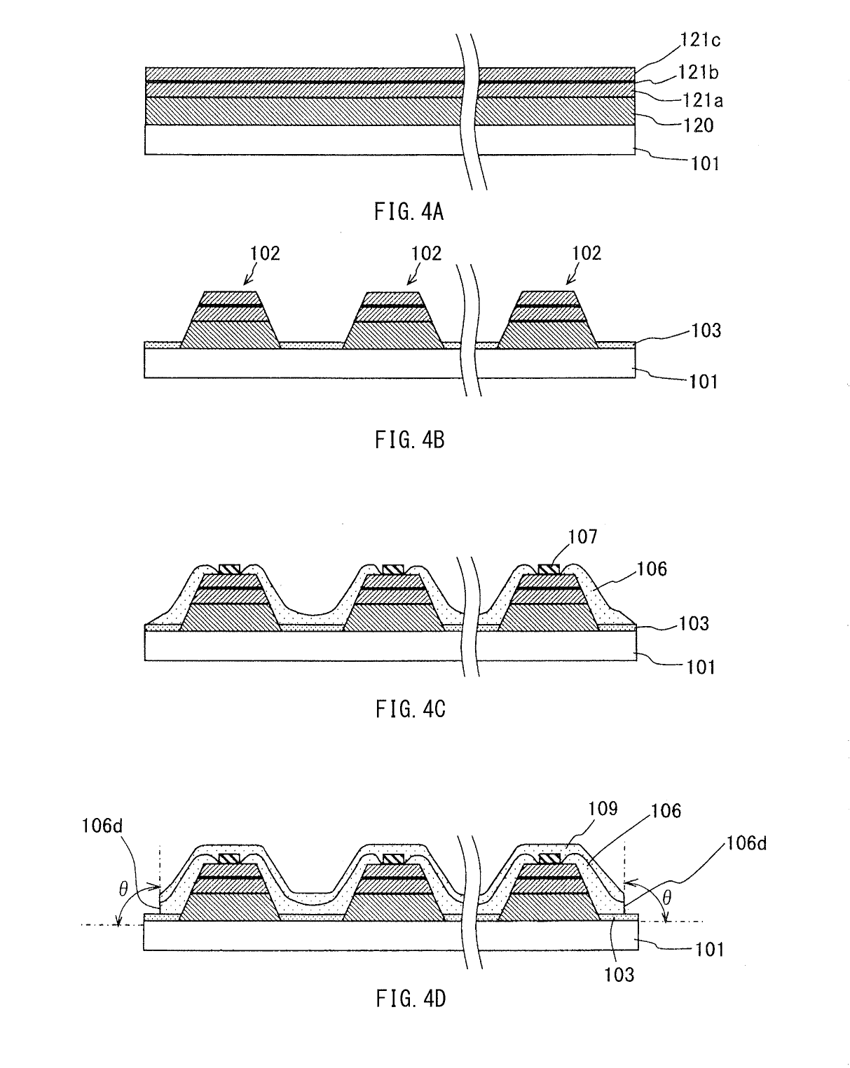

A description is given next of an example method of manufacturing the semiconductor device 100. FIGS. 4A to 4D describe an example manufacturing process of the semiconductor device 100, and are each a cross-sectional view of a main part in a corresponding production step. Note that FIGS. 4A to 4D each illustrate a cross section at a cross-sectional position corresponding to the line B-B of FIG. 1 in the transverse direction of the semiconductor device 100.

Referring to FIG. 4A, a semiconductor stack structure in which the cathode layer 120, the N-cladding layer 121a, the active layer 121b, and the P-cladding layer 121c are stacked may be formed on the substrate 101. Referring to FIG. 4B, through processes including etching and sputtering without limitation, the LEDs 102 and the underlayer insulating film 103 may then be formed on the substrate 101, and the on-substrate wiring lines 104, the common electrode pads 130, and the individual electrode pads 131 as illustrated in FIG. 1 may be formed on the formed underlayer insulating film 103.

Referring to FIG. 4C, an entire region including the on-substrate wiring lines 104, the common electrode pads 130, and the individual electrode pads 131 may then be coated with the organic insulating film 106 with use of a process such as, but not limited to, spin coating and spray coating, followed by patterning of the organic insulating film 106 by means of a photolithography or any other suitable method. The organic insulating film 106 may be made of a resin such as, but not limited to, an epoxy resin, an acrylic resin, and a polyimide resin. Thereafter, the organic insulating film 106 may be processed at a high temperature to round off a pattern of the organic insulating film 106 and thereby to reduce the steps. In view of the organic insulating film 106 which partially covers the light-emitting sections, the organic insulating film 106 may preferable have high transmittance to light emitted from the light-emitting sections.

Further, patterning may be performed on the organic insulating film 106 to form the openings 106a, 106b, and 106c illustrated in FIG. 1 and to remove the organic insulating film 106 on the surfaces of the individual electrode pads 131 and the common electrode pads 130 illustrated in FIG. 1. The common electrode wiring lines 107, the individual electrode wiring lines 108, and the connection wiring lines 132 illustrated in FIG. 1 may be formed on the thus-patterned organic insulating film 106. The common electrode wiring lines 107 may also serve as the anode electrode. In addition, the LEDs 102 may be electrically coupled to their corresponding wire-bonding common electrode pads 130 and wire-bonding individual electrode pads 131. The electrodes and the wiring lines here may be formed as a result of performing a method such as, but not limited to, deposition and sputtering of a metal such as, but not limited to, gold (Au) and aluminum (Al), and performing patterning by means of etching or a lift-off process without limitation.

In this example embodiment, the common electrode wiring line 107 serving also as the anode electrode is coupled directly to the P-cladding layer 121c. In an alternative embodiment, an anode electrode may be formed on the P-cladding layer 121c and the common electrode wiring line 107 may be coupled to the formed anode electrode.

Referring to FIG. 4D, the passivation film 109 may be formed following completion of the process that forms the wiring lines. The passivation film 109 may be an organic insulating film or an inorganic insulating film which may be removed from the surfaces of the individual electrode pads 131 and the common electrode pads 130 by patterning. The passivation film 109 may be preferably thin as long as, to prevent an occurrence of short circuit of the device, the passivation film 109 has a thickness to an extent that the wiring lines, electrodes, and the LEDs 102 are prevented from causing the short circuit.

Eventually, the ends of the pattern in an array direction of the organic insulating film 106 (i.e., the array direction of the LEDs 102) may be processed by means of dry etching or any other suitable method to form the cliff 106d. The cliff 106d may be formed throughout the entire region in the transverse direction of the semiconductor device 100 as illustrated in FIG. 1. In this example embodiment, the passivation film 109 is processed together to form the cliff 106d. In an alternative embodiment, the cliff 106d may be formed first, following which the passivation film 109 may be so formed as to cover the formed cliff 106d.

The cliff 106d may be formed to prevent light having been propagated through the organic insulating film 106 from being directed at least upward from the cliff 106d (i.e., in a direction going away from an upper surface of any LED 102). In this example embodiment, the cliff 106d may be formed into a substantially planar shape, and so formed as to make an angle θ of 90 degrees or less to an upper planar surface of the substrate 101.

In the semiconductor device 100 having the foregoing example configuration, causing a drive current to flow across selected one of the wire-bonding individual electrode pads 131 and selected one of the wire-bonding common electrode pads 130 allows the designated one of the LEDs 102 to emit light. A part of the light emitted from the active layer 121b of that one of the LEDs 102 may be outputted to an upward part of the semiconductor device 100, whereas another part of the light may be guided through the organic insulating film 106. The light having been guided and thus having reached the cliff 106d in the array direction, however, is prevented from traveling at least in a direction that goes away from the substrate 101.

Note that the example embodiment illustrates a configuration in which the cliff 106d is formed only on each end of the pattern in the array direction of the organic insulating film 106 (i.e., the array direction of the LEDs 102). However, the configuration is illustrative and non-limiting, and the cliff 106d may be formed on any end of the pattern in the array direction of the organic insulating film 106 and on any end of the pattern in the direction orthogonal to the array direction.

In the semiconductor device 100 according to this example embodiment, the ends of the pattern in the array direction of the organic insulating film 106 are formed into a cliff-like shape by means of a process including the dry etching. Hence, it is possible to prevent the light emitted from any LED 102 from being leaked, at a location different from a light-emitting region, in a direction that may reduce quality of printing.

### Second Example Embodiment

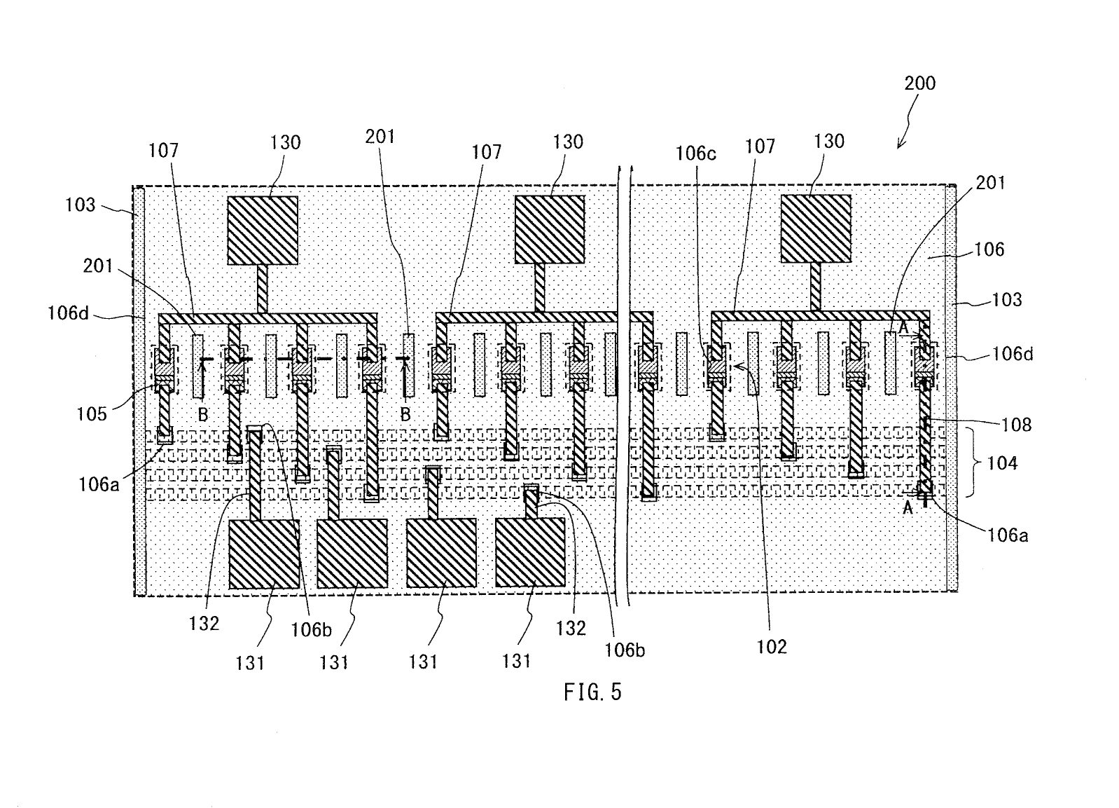

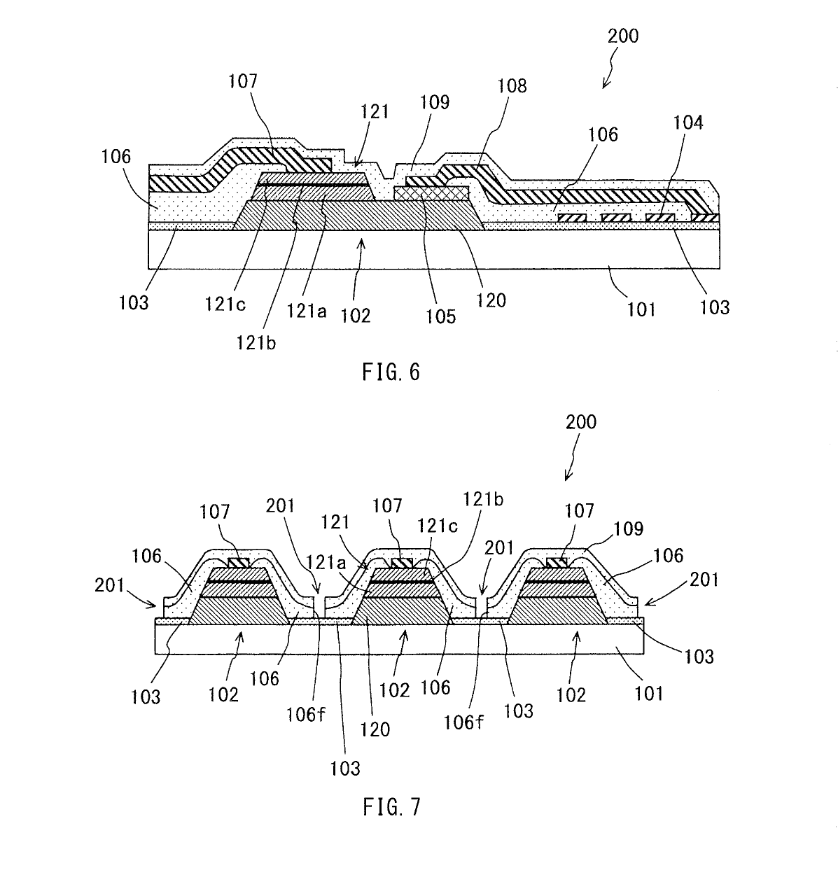

FIG. 5 is a schematic plan view of a main configuration of a semiconductor device 200 according to a second example embodiment of the invention. FIG. 6 is a schematic cross-sectional view, taken along line A-A of FIG. 5, of the semiconductor device 200 illustrated in FIG. 5. FIG. 7 is a schematic cross-sectional view, taken along line B-B of FIG. 5, of the semiconductor device 200 illustrated in FIG. 5. The semiconductor device 200 differs from the semiconductor device 100 according to the foregoing first example embodiment illustrated in FIGS. 1 to 4D, primarily in that a cliff slit 201 is formed between the LEDs 102. Hence, elements in the semiconductor device 200 same as or equivalent to those of the semiconductor device 100 according to the first example embodiment described above are denoted with the same reference numerals, or any drawing may be omitted, to eliminate any redundant description thereof and to focus on a difference between the present example embodiment and the first example embodiment.

Referring to FIGS. 5 and 7, the cliff slits 201 may be formed in respective regions between the LEDs 102. The LEDs 102 may be formed linearly at predetermined intervals on the substrate 101 in the longitudinal direction of the substrate 101. The cliff slits 201 each may serve as a non-limiting example of a first slit. The cliff slits 201 may be so formed longer than the LEDs 102 as to extend beyond formation regions of the respective LEDs 102 in the transverse direction of the substrate 101, and may be formed at least on the organic insulating film 106. In this example embodiment, the cliff slits 201 may be formed continuously on the organic insulating film 106 and the passivation film 109 as illustrated in FIG. 7 for convenience of an example manufacturing process to be described later.

The cliff slits 201 each may have a cliff 106f The cliff 106f may serve as a non-limiting example of a second cliff of the organic insulating film 106. The cliff 106f may be formed to prevent the light having been propagated through the organic insulating film 106 from being directed at least upward from the cliff 106f (i.e., in the direction going away from the upper surface of any LED 102). In this example embodiment, the cliff 106f may be formed into a substantially planar shape, and so formed as to make the angle θ (see FIG. 4C) of 90 degrees or less to the upper planar surface of the substrate 101.

A method of manufacturing the semiconductor device 200 according to this example embodiment differs from the method of manufacturing the semiconductor device 100 according to the first example embodiment described with reference to FIGS. 4A to 4D, in that the cliff slits 201 are formed in the process step illustrated in FIG. 4D, i.e., formed at the timing in which the ends of the pattern in the array direction of the organic insulating film 106 (i.e., the array direction of the LEDs 102) are processed by means of the dry etching or any other suitable method to form the cliff 106d. Otherwise, the method of manufacturing the semiconductor device 200 according to this example embodiment is similar to the method of manufacturing the semiconductor device 100 according to the first example embodiment described with reference to FIGS. 4A to 4D, and any redundant description thereof is therefore omitted.

In this example embodiment, the passivation film 109 is processed together to form the cliff 106f In an alternative embodiment, the cliff 106f may be formed first, following which the passivation film 109 may be so formed as to cover the formed cliff 106f.

In the semiconductor device 200 according to this example embodiment, the cliffs are formed substantially in the same conditions as each other around the LEDs of the LED lines. This allows an influence of the propagation of the light that affects light emission of the LEDs to be substantially uniform. Hence, it is possible to overcome, for example but not limited to, an inconvenience in which the LEDs located on both ends are affected by the influence of the propagation of the light more than those located in any other region and thereby an amount of light emission fails to be uniform.

### Third Example Embodiment

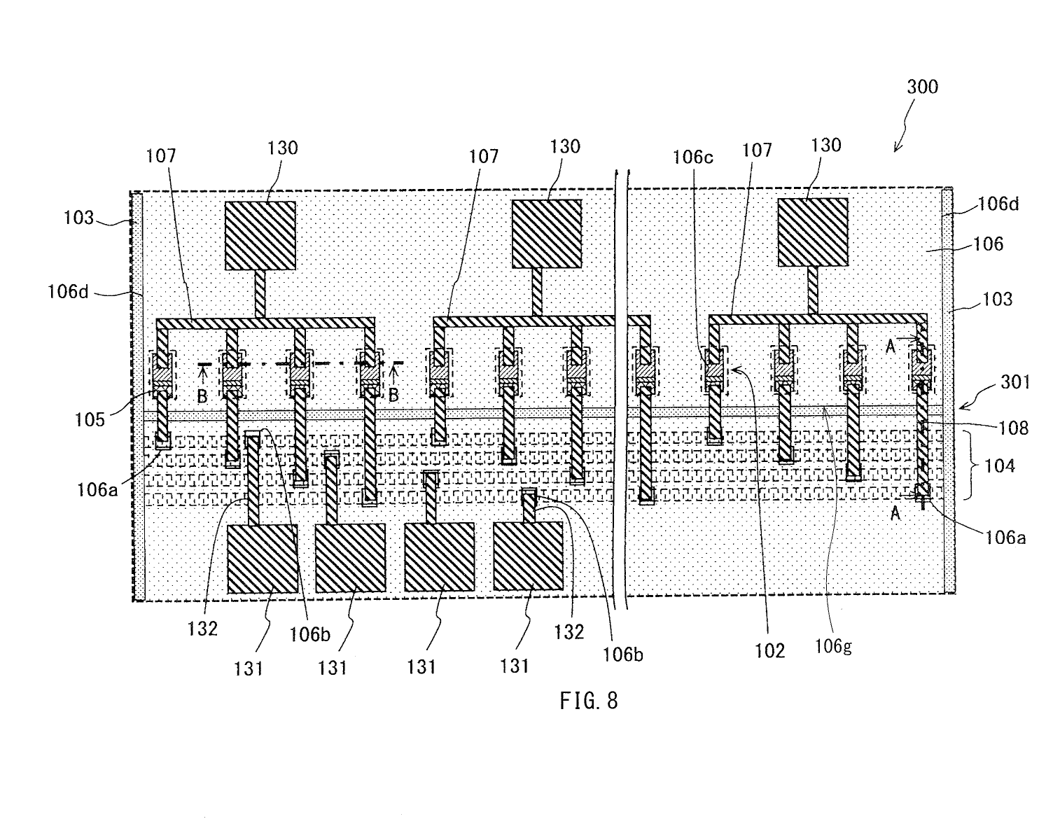

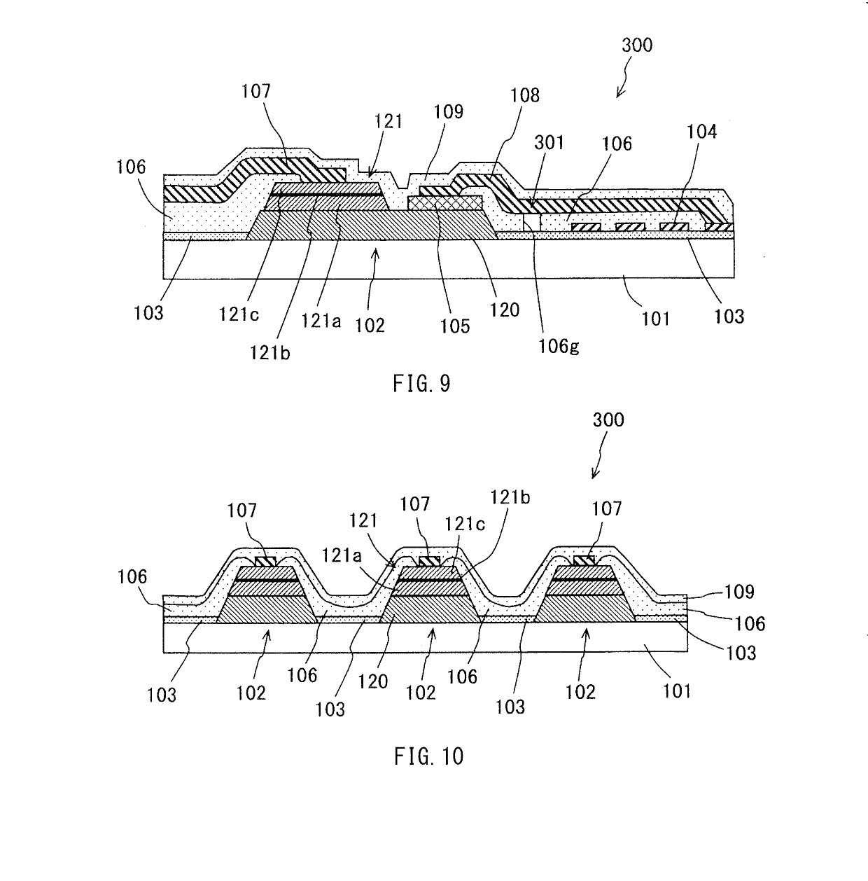

FIG. 8 is a schematic plan view of a main configuration of a semiconductor device 300 according to a third example embodiment of the invention. FIG. 9 is a schematic cross-sectional view, taken along line A-A of FIG. 8, of the semiconductor device 300 illustrated in FIG. 8. FIG. 10 is a schematic cross-sectional view, taken along line B-B of FIG. 8, of the semiconductor device 300 illustrated in FIG. 8. The semiconductor device 300 differs from the semiconductor device 100 according to the foregoing first example embodiment illustrated in FIGS. 1 to 4D, primarily in that a cliff slit 301 is formed along the LED lines between the on-substrate wiring lines 104 and the LED lines. Hence, elements in the semiconductor device 300 same as or equivalent to those of the semiconductor device 100 according to the first example embodiment described above are denoted with the same reference numerals, or any drawing may be omitted, to eliminate any redundant description thereof and to focus on a difference between the present example embodiment and the first example embodiment.

Referring to FIGS. 8 and 9, in this example embodiment, the cliff slit 301 may be formed along the LED lines between the on-substrate wiring lines 104 and the LED lines. The cliff slit 301 may serve as a non-limiting example of a second slit. The cliff slit 301 may be formed, in the longitudinal direction of the substrate 101, on the organic insulating film 106 throughout the entire formation region of the organic insulating film 106.

The cliff slit 301 may have a cliff 106g. The cliff 106g may serve as a non-limiting example of a third cliff of the organic insulating film 106. The cliff 106g may be formed to prevent the light having been propagated through the organic insulating film 106 from being directed at least upward from the cliff 106g (i.e., in a direction going away from a formation surface of any LED 102). In this example embodiment, the cliff 106g may be formed into a substantially planar shape, and so formed as to make the angle θ (see FIG. 4C) of 90 degrees or less to the upper planar surface of the substrate 101.

A method of manufacturing the semiconductor device 300 according to this example embodiment differs from the method of manufacturing the semiconductor device 100 according to the first example embodiment described with reference to FIGS. 4A to 4D, in that the cliff slit 301 is formed in the process step illustrated in FIG. 4C, i.e., formed by means of dry etching or any other suitable method after the entire region including the on-substrate wiring lines 104, the common electrode pads 130, and the individual electrode pads 131 are coated with the organic insulating film 106 and after the organic insulating film 106 is patterned. Otherwise, the method of manufacturing the semiconductor device 300 according to this example embodiment is similar to the method of manufacturing the semiconductor device 100 according to the first example embodiment described with reference to FIGS. 4A to 4D, and any redundant description thereof is therefore omitted.

Note that the example embodiment illustrates an example in which the cliff slit 301 is formed prior to the process step in which the wiring lines are formed. In an alternative embodiment, as in the second example embodiment described above, the cliff slit 301 may be formed in the process step illustrated in FIG. 4D, i.e., formed together at the timing in which the ends of the pattern in the array direction of the organic insulating film 106 (i.e., the array direction of the LEDs 102) are processed by means of the dry etching or any other suitable method to form the cliff 106d. In this case, the organic insulating film 106 may remain at a lower part of the individual electrode wiring lines 108; however, the upward leakage of light is prevented by the individual electrode wiring lines 108.

In the semiconductor device 300 according to this example embodiment, the cliff is formed between the LED lines and the on-substrate wiring lines 104. Hence, it is possible to prevent the light having been guided through the organic insulating film 106 from being leaked from, for example but not limited to, the openings 106a and 106b of the organic insulating film 106 or from any other region which may lead to a reduction in quality of printing.

### Fourth Example Embodiment

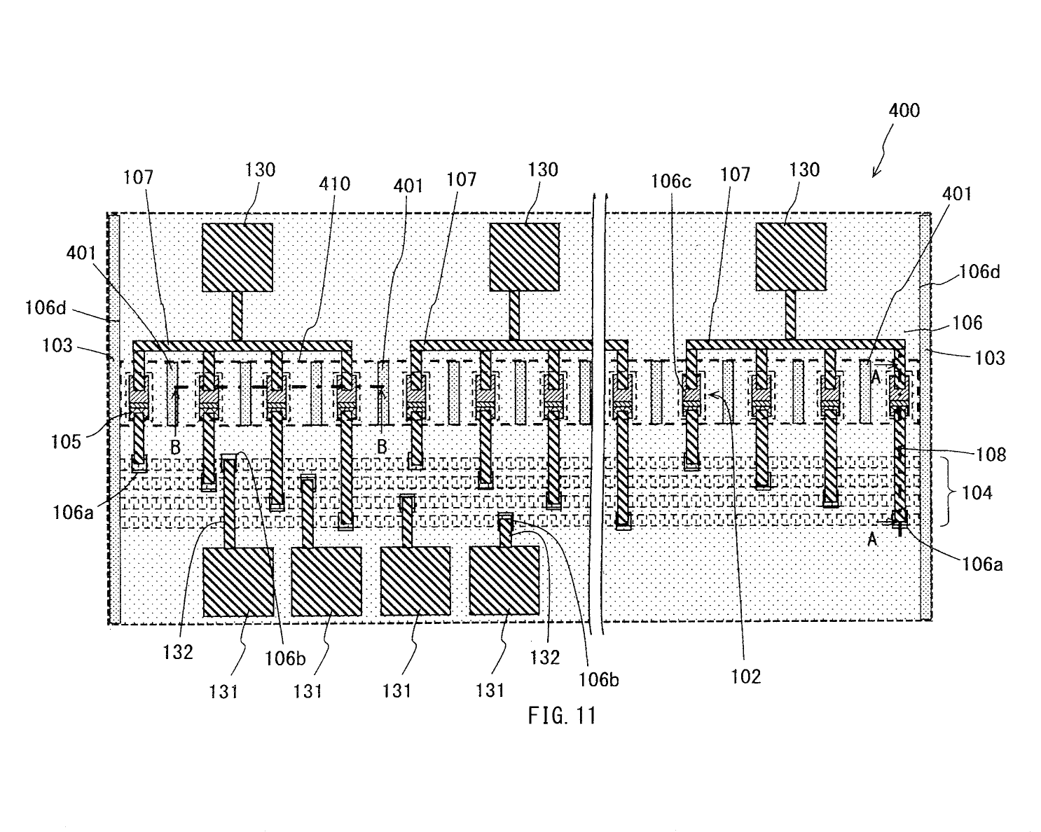

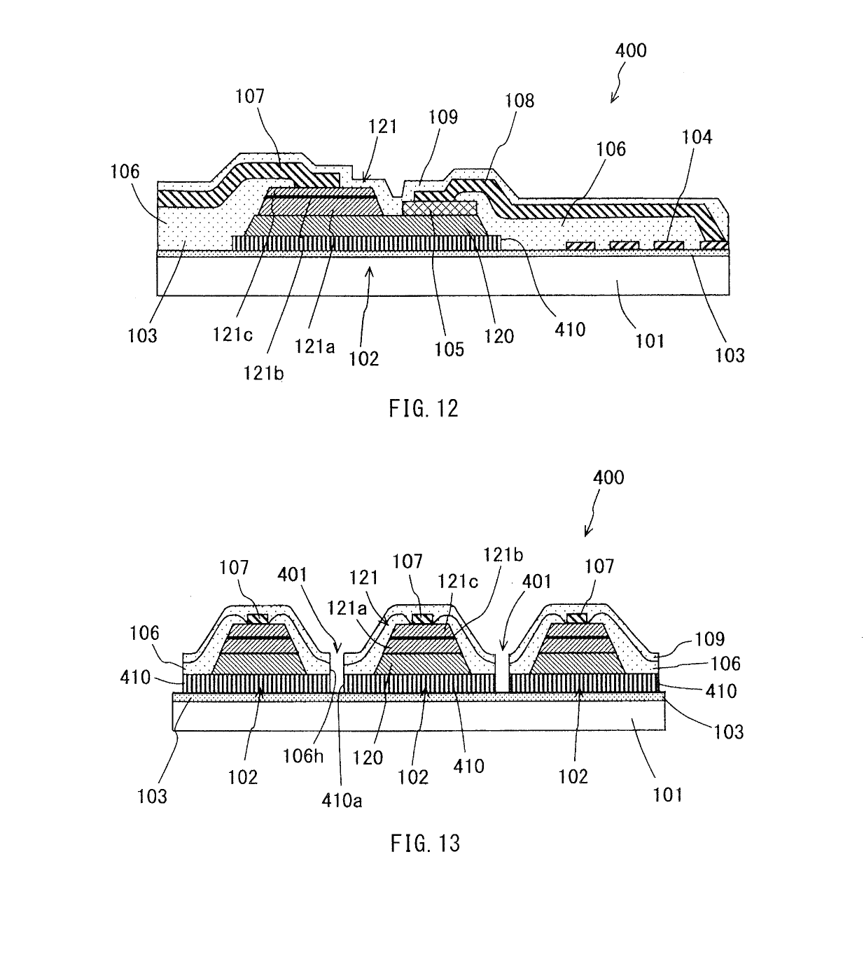

FIG. 11 is a schematic plan view of a main configuration of a semiconductor device 400 according to a fourth example embodiment of the invention. FIG. 12 is a schematic cross-sectional view, taken along line A-A of FIG. 11, of the semiconductor device 400 illustrated in FIG. 11. FIG. 13 is a schematic cross-sectional view, taken along line B-B of FIG. 11, of the semiconductor device 400 illustrated in FIG. 11.

The semiconductor device 400 differs from the semiconductor device 200 according to the foregoing second example embodiment illustrated in FIGS. 5 to 7, primarily in that a semiconductor thin film is used to form the device as described later and thereby a planarizing film is provided at a lower part of the LED lines. Hence, elements in the semiconductor device 400 same as or equivalent to those of the semiconductor device 100 according to the first example embodiment described above are denoted with the same reference numerals to eliminate any redundant description thereof and to focus on a difference between the present example embodiment and the first example embodiment.

Referring to FIGS. 11 to 13, a planarizing film 410 is formed at a lower layer of the LED lines in this example embodiment. Note that FIG. 11 denotes only an outline of the planarizing film 410 with a dotted line.

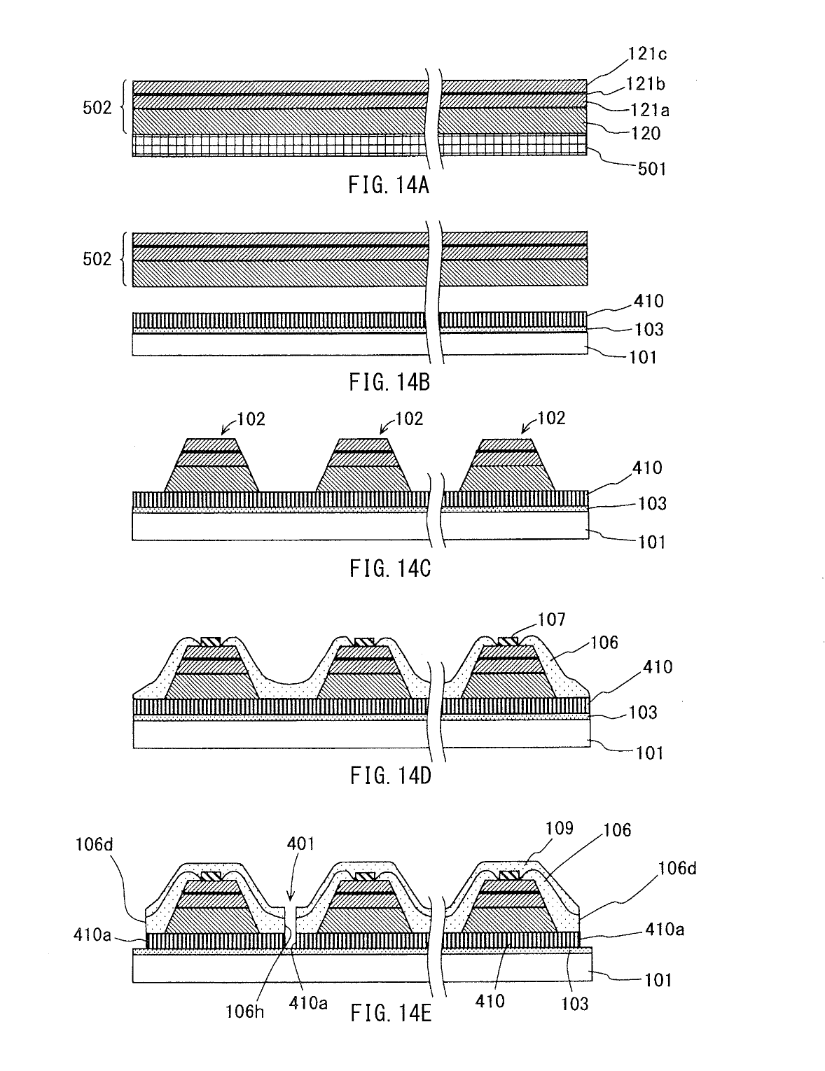

Both the organic insulating film 106 and the planarizing film 410 may be removed by a predetermined width throughout the entire region in the transverse direction on both ends of the semiconductor device 400 in the array direction (i.e., the longitudinal direction) of the LED lines. Also, an end of the organic insulating film 106 may be formed with the cliff 106d, whereas an end of the planarizing film 410 may be formed with a cliff 410a as illustrated in FIG. 14E to be referred to later.

Cliff slits 401 may be formed in respective regions between the LEDs 102. The LEDs 102 may be formed linearly at predetermined intervals in the longitudinal direction of the substrate 101. The cliff slits 401 may be so formed as to extend beyond formation regions of the respective LEDs 102 in the transverse direction of the substrate 101. The cliff slits 401 each may have a length substantially equal to a width of the planarizing film 410, and may be formed at least on the organic insulating film 106 and the planarizing film 410. In this example embodiment, the cliff slits 401 may be formed continuously, including the passivation film 109, on the organic insulating film 106 and the planarizing film 410 as illustrated in FIG. 13 for convenience of an example manufacturing process to be described later.

The cliff slits 401 each may have a cliff 106h and the cliff 410a. The cliff 410a may serve as a non-limiting example of a fourth cliff of the planarizing film 410. The cliff 106h of the organic insulating film 106 and the cliff 410a of the planarizing film 410 may be formed to prevent the light having been propagated through the organic insulating film 106 and the planarizing film 410 from being directed at least upward from the cliffs 106h and 410a (i.e., in the direction going away from the formation surface of any LED 102). In this example embodiment, the cliffs 106h and 410a each may be formed into a substantially planar shape, and so formed as to make the angle θ (see FIG. 4C) of 90 degrees or less to the upper planar surface of the substrate 101.

A description is given next of an example method of manufacturing the semiconductor device 400. FIGS. 14A to 14E describe an example manufacturing process of the semiconductor device 400, and are each a cross-sectional view of a main part in a corresponding production step. Note that FIGS. 14A to 14E each illustrate a cross section at a cross-sectional position corresponding to the line B-B of FIG. 11 in the transverse direction of the semiconductor device 400.

Referring to FIG. 14A, a semiconductor thin film 502 may be formed on a growth substrate 501 with a removable sacrificing layer in between. Note that the growth substrate 501 may be provided separately from the substrate 101 of the semiconductor device 400. The semiconductor thin film 502 may have a semiconductor stack structure in which the cathode layer 120, the N-cladding layer 121a, the active layer 121b, and the P-cladding layer 121c are stacked.

Referring to FIG. 14B, the underlayer insulating film 103 may be formed on the substrate 101 of the semiconductor device 400, following which the planarizing film 410 may be formed in a predetermined region in which the LED lines are located as illustrated in FIG. 11. For example, the planarizing film 410 may be an organic insulating film made of a resin material that allows for formation of a film by means of coating. Non-limiting examples of the resin may include a polyimide resin and a novolak-based resin. Also, the material of such an organic insulating film may have photosensitivity to allow for formation of the planarizing film 410 only in any region.

Then, the semiconductor thin film 502 may be separated from the growth substrate 501 to bond the separated semiconductor thin film 502 onto the substrate 101 at a predetermined position on the planarizing film 410 formed on the substrate 101.

Referring to FIG. 14C, through processes including etching and sputtering without limitation, the LEDs 102 may then be formed on the substrate 101, and the on-substrate wiring lines 104, the common electrode pads 130, and the individual electrode pads 131 as illustrated in FIG. 11 may be formed on the underlayer insulating film 103.

Referring to FIG. 14D, an entire region including the on-substrate wiring lines 104, the common electrode pads 130, and the individual electrode pads 131 may then be coated with the organic insulating film 106 with use of a process such as, but not limited to, spin coating and spray coating, followed by patterning of the organic insulating film 106 by means of a photolithography or any other suitable method. The organic insulating film 106 may be made of a resin such as, but not limited to, an epoxy resin, an acrylic resin, and a polyimide resin. Thereafter, the organic insulating film 106 may be processed at a high temperature to round off the pattern of the organic insulating film 106 and thereby to reduce the steps. In view of the organic insulating film 106 which partially covers the light-emitting sections, the organic insulating film 106 may preferable have high transmittance to the light emitted from the light-emitting sections.

Further, the patterning may be performed on the organic insulating film 106 to form the openings 106a, 106b, and 106c and to remove the organic insulating film 106 on the surfaces of the individual electrode pads 131 and the common electrode pads 130. The common electrode wiring lines 107 serving as the anode electrode, the individual electrode wiring lines 108, and the connection wiring lines 132 may be formed on the thus-patterned organic insulating film 106. In addition, the LEDs 102 may be electrically coupled to their corresponding wire-bonding common electrode pads 130 and wire-bonding individual electrode pads 131. The electrodes and the wiring lines here may be formed as a result of performing a method such as, but not limited to, deposition and sputtering of a metal such as, but not limited to, gold (Au) and aluminum (Al), and performing patterning by means of etching or a lift-off process without limitation.

Referring to FIG. 14E, the passivation film 109 may be formed following completion of the process that forms the wiring lines. The passivation film 109 may be an organic insulating film or an inorganic insulating film which may be removed from the surfaces of the individual electrode pads 131 and the common electrode pads 130 by patterning. The passivation film 109 may be preferably thin as long as, to prevent an occurrence of short circuit of the device, the passivation film 109 has a thickness to an extent that the wiring lines, electrodes, and the LEDs 102 are prevented from causing the short circuit.

Eventually, the ends of the pattern in the array direction of the organic insulating film 106 and the planarizing film 410 (i.e., the array direction of the LEDs 102) as well as formation regions of the respective cliff slits 401 may be processed by means of dry etching or any other suitable method to form the cliffs 106d and 106h of the organic insulating film 106 and the cliff 410a of the planarizing film 410. In this example embodiment, the passivation film 109 is processed together to form the cliffs 106d, 106h, and 410a. In an alternative embodiment, the cliffs 106d, 106h, and 410a may be formed first, following which the passivation film 109 may be so formed as to cover the formed cliffs 106d, 106h, and 410a.

The cliffs 106d, 106h, and 410a may be formed to prevent the light having been propagated through the organic insulating film 106 and the planarizing film 410 from being directed at least upward from the cliffs 106d and 410a (i.e., in the direction going away from the formation surface of any LED 102). In this example embodiment, the cliffs 106d, 106h, and 410a each may be formed into a substantially planar shape, and so formed as to make the angle θ (see FIG. 4C) of 90 degrees or less to the upper planar surface of the substrate 101.

Note that the example embodiments described above have been described with reference to their respective examples in which the cliff slits 201 according to the second example embodiment and the cliff slit 301 according to the third example embodiments are formed on their respective separate semiconductor devices. In an alternative embodiment, a semiconductor device may have a configuration in which the cliff slits 201 and 301 according to the second and the third example embodiments are provided together. Also, the fourth example embodiment illustrates an example in which the planarizing film 410 is incorporated in the semiconductor device having the configuration according to the second example embodiment. In an alternative embodiment, the planarizing film 410 may be employed in a semiconductor device having the configuration according to the first example embodiment, the configuration according to the third example embodiment, or a configuration that includes any combination of the first, the second, and the third example embodiments.

In the semiconductor device 400 according to this example embodiment, the ends of the pattern in the array direction of the organic insulating film 106 and the planarizing film 410 are formed into a cliff-like shape by means of a process including the dry etching. Hence, it is possible to prevent the light emitted from any LED 102 from being leaked, at a location different from a light-emitting region, in a direction that may reduce quality of printing. Also, the cliffs are formed substantially in the same conditions as each other around the LEDs of the LED lines. This allows an influence of the propagation of the light that affects light emission of the LEDs to be substantially uniform. Hence, it is possible to overcome, for example but not limited to, an inconvenience in which the LEDs located on both ends are affected by the influence of the propagation of the light more than those located in any other region and thereby an amount of light emission fails to be uniform.

### Fifth Example Embodiment

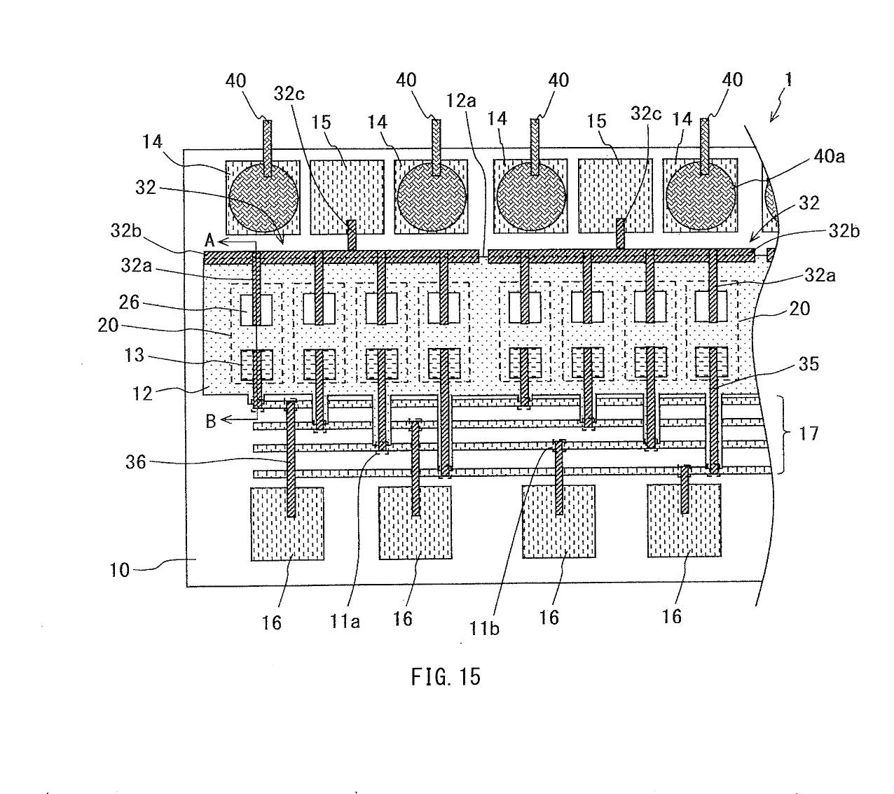

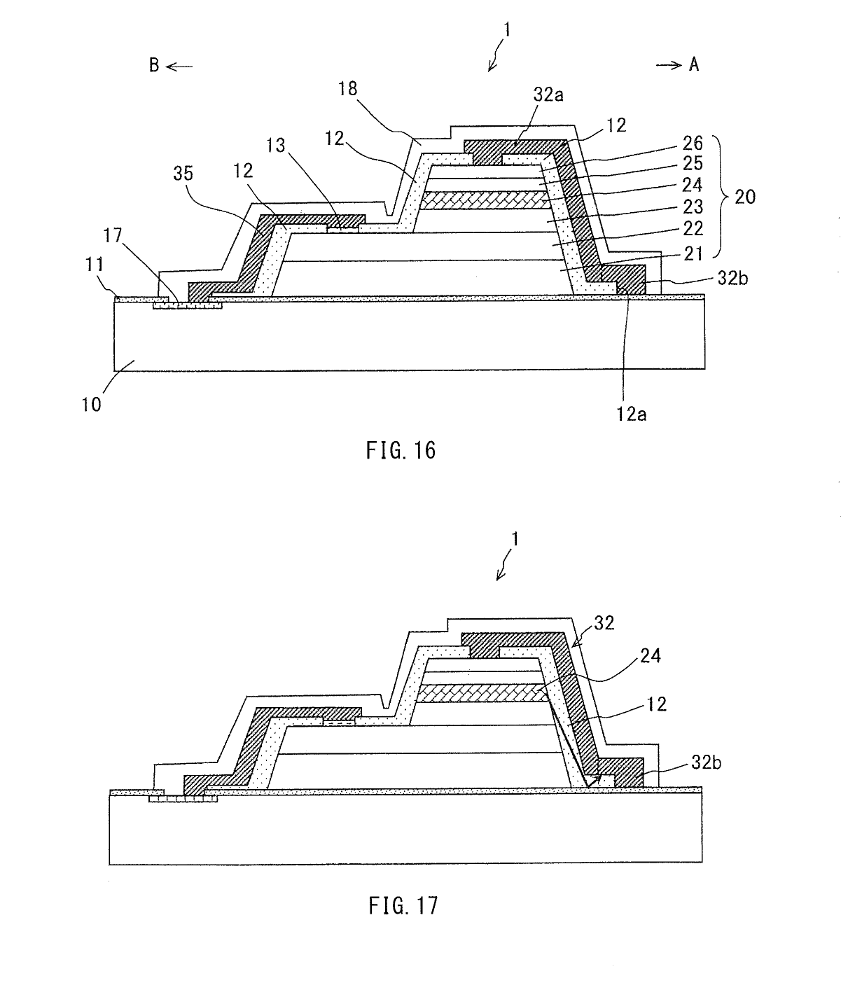

FIG. 15 is a schematic plan view of a main configuration of a semiconductor device 1 according to a fifth example embodiment of the invention. FIG. 16 is a schematic cross-sectional view, taken along line A-B of FIG. 15, of the semiconductor device 1 illustrated in FIG. 15. Note that an interlayer insulating film layer 11 and a passivation layer 18 to be described later are omitted in FIG. 15 for easier illustration.

Referring to FIGS. 15 and 16, the interlayer insulating film layer 11 (see FIG. 16) may be formed on a drive circuit substrate 10, and a plurality of LEDs 20 may be joined onto the interlayer insulating film layer 11. The drive circuit substrate 10 may serve as a non-limiting example of a substrate, and may have an elongated plate-like shape. The LEDs 20 may be formed linearly at predetermined intervals in a longitudinal direction of the drive circuit substrate 10. The LEDs 20 each may serve as a non-limiting example of a light-emitting element. The LEDs 20 formed above the drive circuit substrate 10 each may have multiple layers. Referring to FIG. 16, each of the LEDs 20 may have a configuration in which a buffer layer 21, an N-contact layer 22, a lower cladding layer 23, an active layer 24, an upper cladding layer 25, and a P-contact layer 26 are stacked in the order from the bottom. A constituent material of each of the LEDs 20 may be a GaAs-based semiconductor, non-limiting examples of which may include an N-GaAs semiconductor, an N-AlxGa(1−x)As semiconductor, a P-GaAs semiconductor, and a P-AlxGa(1−x)As semiconductor.

The LEDs 20 each may be processed into a mesa shape with use of a technology such as, but not limited to, photolithography and etching, and may have an outermost surface from which the N-contact layer 22 and the P-contact layer 26 may be exposed. A cathode electrode 13 serving as an electrode may be formed on the N-contact layer 22. The cathode electrode 13 may be formed with use of a method such as, but not limited to, deposition and sputtering.

A surface of the drive circuit substrate 10 may be formed with on-substrate wiring lines 17 that may be formed in a side-by-side fashion in four lines along the LEDs 20 arrayed in the longitudinal direction of the drive circuit substrate 10. Such LEDs 20 may be hereinafter referred to as “LED lines”. A region on the drive circuit substrate 10 may also include individual electrode pads 16, common electrode pads 15, and external connection pads 14. In this non-limiting embodiment, four individual electrode pads 16 may be formed adjacent to each other at a location on the side of the on-substrate wiring lines 17 opposite to the LED lines. The common electrode pads 15 and the external connection pads 14 may be formed in a line at a location on the side of the LED lines opposite to the on-substrate wiring lines 17. The common electrode pads 15 may serve as connection terminals, and each may be disposed corresponding to a group of four LEDs 20. The external connection pads 14 each may be formed on both sides of one of the common electrode pads 15, and each may allow one of external connection wiring lines 40 to be coupled thereto by means of bonding. The external connection pads 14 each may thus serve as a wire connection pad and formed with a bonding part 40a.

The drive circuit substrate 10 may include a drive circuit that drives the LED lines. The drive circuit may supply any of the external connection pads 14 with drive power to supply a drive current across selected one of the common electrode pads 15 and selected one of the individual electrode pads 16. The drive circuit may perform a matrix control to supply the drive current by which the LED lines are driven and the LED lines emit light.

The interlayer insulating film layer 11 may be formed in a region on the drive circuit substrate 10, excluding regions on the external connection pads 14, the common electrode pads 15, the individual electrode pads 16, and openings 11a and 11b formed at connection parts that correspond to the on-substrate wiring lines 17. Note that the openings 11a and 11b are each denoted with a dotted line in FIG. 15.

The LEDs 20 each may be electrically coupled to one of the common electrode wiring lines 32 serving as a non-limiting example of a “wiring line” and one of the individual electrode wiring lines 35 serving as a non-limiting example of the “wiring line”. Before the formation of those wiring lines, an insulating film 12 may be formed as an underlayer of the common electrode wiring lines 32 and the individual electrode wiring lines 35. The insulating film 12 may cover steps formed across the layers of each of the LEDs 20 as illustrated in cross-sectional FIG. 16 to thereby reduce the steps. Also, to ensure insulation between the on-substrate wiring lines 17 and the individual electrode wiring lines 35, the insulating film 12 may be formed in a region that covers the LED lines as a whole and a region as a lower layer of each of the individual electrode wiring lines 35. Note that the regions in which the insulating film 12 is formed may exclude a predetermined location at a surface of each of the LEDs 20, i.e., openings formed on the P-contact layers 26 and the cathode electrodes 13.

The P-contact layers 26 of the respective LEDs 20 may be electrically coupled to the common electrode wiring line 32 that may also serve as an anode electrode. The common electrode wiring line 32 may be formed on the insulating film 12 by which the steps are reduced, and may electrically couple the P-contact layers 26 of the grouped, mutually-adjacent four LEDs 20 with corresponding one of the common electrode pads 15 as illustrated in FIG. 15.

The common electrode wiring line 32 may be configured by a shielding connection section 32b, electrode sections 32a, and a pad connection section 32c. The shielding connection section 32b may be so formed as to cover an end of the insulating film 12, i.e., as to cover a transverse direction end 12a that extends in the longitudinal direction while facing the external connection pads 14. The electrode sections 32a each may extend perpendicularly from the shielding connection section 32b to the P-contact layer 26 of one of the LEDs 20. The pad connection section 32c may extend perpendicularly from the shielding connection section 32b to corresponding one of the common electrode pads 15 in a direction opposite to the electrode section 32a.

The shielding connection section 32b may be so formed as to entirely cover both an upper part and an end of the transverse direction end 12a of the insulating film 12 as illustrated in FIG. 16. Also, a slight gap may be formed between one shielding connection section 32b and another shielding connection section 32b which are adjacent to each other to ensure insulation therebetween as illustrated in FIG. 15. In other words, the shielding connection section 32b may have a width that corresponds at least to one or more of the LEDs 20 and thereby so extend to cover, in the array direction of the LEDs 20, the transverse direction end 12a of the insulating film 12 which extends in the array direction (i.e., the longitudinal direction of the drive circuit substrate 10) of the LEDs 20.

The cathode electrodes 13 of the respective LEDs 20 may be electrically coupled to their respective individual electrode wiring lines 35. The individual electrode wiring lines 35 each may be formed on the insulating film 12 by which the steps are reduced and the individual electrode wiring lines 35 are insulated from the on-substrate wiring lines 17. Also, as illustrated in FIG. 15, the individual electrode wiring lines 35 each may allow only the cathode electrode 13 of any LED 20 and its corresponding predetermined one of the on-substrate wiring lines 17 to be electrically coupled to each other through corresponding one of the openings 11a formed on the interlayer insulating film layer 11.

The four individual electrode pads 16 may be electrically coupled to their respective connection wiring lines 36. The connection wiring lines 36 each may be formed on the interlayer insulating film layer 11, and electrically coupled to only corresponding one of the on-substrate wiring lines 17 through corresponding one of the openings 11b formed on the interlayer insulating film layer 11. A passivation layer 18 as illustrated in FIG. 16 may be formed on an upper surface of the semiconductor device 1 to prevent an occurrence of short circuit attributable to a factor such as, but not limited to, dust. The passivation layer 18 may be formed in a region excluding the surfaces of the external connection pads 14.

With the example configuration described above, causing a current to flow from the anode electrode, e.g., the common electrode wiring line 32, to the cathode electrode 13 of any of the desired LEDs 20 allows the active layer 24 of that LED 20 to emit light.

A description is given next of an example method of manufacturing the semiconductor device 1.

First, the drive circuit substrate 10 is prepared that may be provided with the drive circuit, and that may include, on the surface, the external connection pads 14, the common electrode pads 15, the individual electrode pads 16, and the on-substrate wiring lines 17. Then, the interlayer insulating film layer 11 may be formed on the drive circuit substrate 10 excluding regions on the external connection pads 14, the common electrode pads 15, the individual electrode pads 16, and the openings 11a and 11b formed at the connection parts of the on-substrate wiring lines 17. Thereafter, the LEDs 20 each provided with the cathode electrode 13 may be disposed and subjected to joining at their predetermined locations on the interlayer insulating film layer 11.

Then, the insulating film 12 may be formed in a region that covers the LED lines as a whole and in a region that serves as an underlayer of the individual electrode wiring lines 35, excluding predetermined locations on a surface of each of the LEDs 20 including a wiring line connection part that corresponds to the P-contact layer 26 and a wiring line connection part that corresponds to the cathode electrode 13 on the N-contact layer 22. Thereafter, the common electrode wiring line 32, the individual electrode wiring lines 35, and the connection wiring lines 36 may be formed together in the same process step, following which the passivation layer 18 as illustrated in FIG. 16 may be so formed as to cover an entire region except for surfaces of the respective external connection pads 14.

The cathode electrodes 13, the common electrode wiring line 32, the individual electrode wiring lines 35, and the connection wiring lines 36 may be made of a metal such as, but not limited to, aluminum (Al), titanium (Ti), and gold (Au), and formed using deposition, sputtering, or any other suitable method. The P-contact layers 26 may be so formed that the common electrode wiring line 32 comes into direct contact with the P-contact layer 26, in view of a low contact resistance between P-GaAs that may constitutes the P-contact layers 26 and a metal constituting the common electrode wiring line 32.

To form the interlayer insulating film layer 11, the insulating film 12, and the passivation layer 18 such that they prevent an occurrence of short circuit, the interlayer insulating film layer 11, the insulating film 12, and the passivation layer 18 may be an organic film having an insulating property or an inorganic film having an insulating property. The organic film may be made of a material such as, but not limited to, a polyimide resin and an acrylic resin, whereas the inorganic film may be made of a material such as, but not limited to, a nitride and an oxide. In one embodiment where the interlayer insulating film layer 11, the insulating film 12, and the passivation layer 18 are each an organic insulating film, an intended pattern may be formed with use of a photolithography technique, following which curing may be performed by means of a high-temperature process. In one embodiment where the interlayer insulating film layer 11, the insulating film 12, and the passivation layer 18 are each an inorganic insulating film, a film may be formed entirely on a surface with use of CVD, sputtering, or any other suitable method, following which formation of a mask with use of a lift-off process, photolithography, or any other suitable method and a subsequent etching may be performed to form a pattern.

To prevent an occurrence of disconnection attributed to steps upon formation of the common electrode wiring line 32, the individual electrode wiring lines 35, and the connection wiring lines 36, it is preferable that the interlayer insulating film layer 11, the insulating film 12, and the passivation layer 18 be thin to the extent that they prevent the occurrence of short circuit. Also, in view of the insulating film 12 and the passivation layer 18 which may be formed on the LEDs 20, it is preferable that the insulating film 12 and the passivation layer 18 be made of a material that has high transmittance to light of a wavelength corresponding to a wavelength of light emitted from the active layer 24 and thus does not disturb extraction of the light to the outside.

In the semiconductor device 1 having the foregoing example configuration, causing a drive current to flow across selected one of the common electrode pads 15 and selected one of the individual electrode pads 16 allows the corresponding one of the LEDs 20 to emit light. A part of the light emitted from the active layer 24 of that one of the LEDs 20 may be outputted to an upward part of the semiconductor device 1, whereas another part of the light may be transmitted through the insulating film 12 as denoted by an arrow in FIG. 17 to reach a region near the transverse direction end 12a of the insulating film 12. Note that the multiple LEDs 20 may be selected together to allow each of the selected LEDs 20 to emit light.

The light having been transmitted through the insulating film 12, however, is blocked and thus subjected to light shielding by the shielding connection section 32b of the common electrode wiring line 32 so formed as to cover the transverse direction end 12a of the insulating film 12. Hence, it is possible to prevent a leakage of light from the region near the transverse direction end 12a.

Note that the example embodiment illustrates a configuration in which the common electrode wiring line 32 only covers the transverse direction end 12a of the insulating film 12 to prevent the light having been propagated through the insulating film 12 from being reflected upward by the connection wiring lines 40 or by any other elements. However, the configuration is illustrative and non-limiting, and the common electrode wiring line 32 may be so formed as to cover not only the transverse direction end 12a of the insulating film 12 but also any end in the longitudinal direction of the insulating film 12.

Also, in this example embodiment, the common electrode wiring line 32 serving also as the anode electrode is coupled directly to the P-contact layer 26. In an alternative embodiment, an anode electrode may be formed on the P-contact layer 26 and the common electrode wiring line 32 may be coupled to the formed anode electrode.

Further, the example embodiment illustrates a configuration in which the drive circuit substrate 10 is provided with the drive circuit of the LEDs 20. However, the configuration is illustrative and non-limiting, and thus any of various configurations may be employed. For example, a configuration may be employed in which the drive current is caused to flow across selected one of the common electrode pads 15 and selected one of the individual electrode pads 16 directly from an external drive circuit.

In the semiconductor device 1 according to this example embodiment, the light that propagates through the insulating film 12 is prevented from being reflected upward by a reflective structure such as, but not limited to, the connection wiring lines 40. Hence, it is possible to prevent a reduction in quality, resulting from a noise attributed to reflection light, of printing in a printer. Also, the light shielding is achieved by the formation of the shielding connection section 32b that are based on a shape of the pattern of the wiring line such as, but not limited to, the common electrode wiring line 32. This does not involve the necessity of newly providing a process step of forming a light-shielding film, making it possible to prevent a rise in costs.

### Sixth Example Embodiment

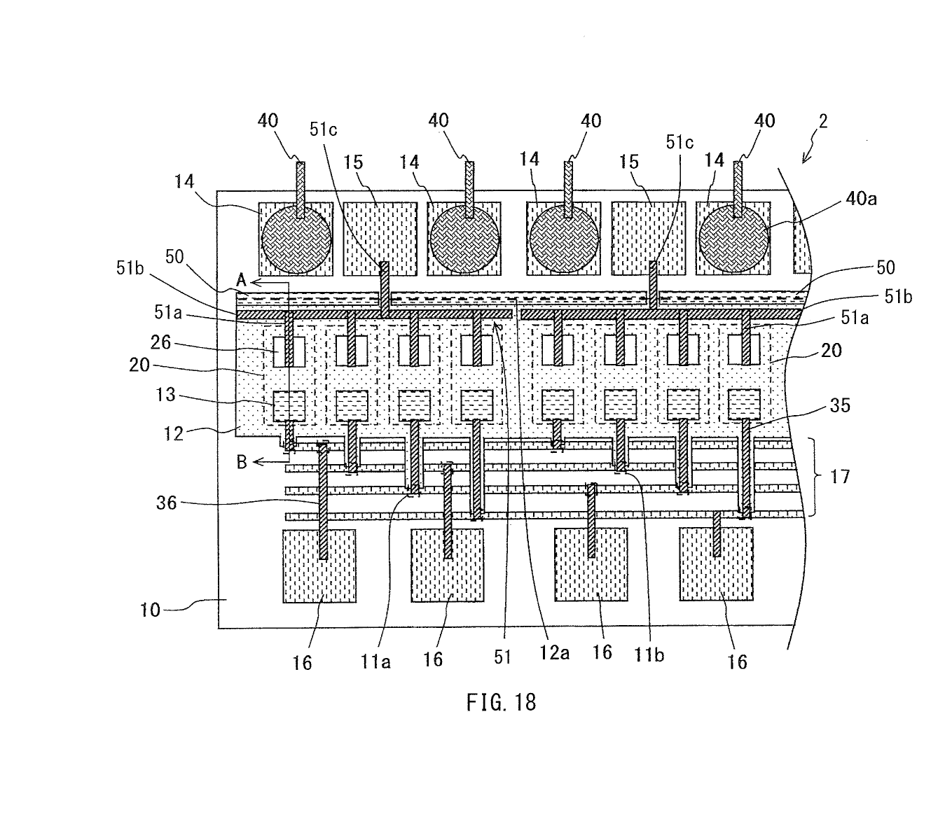

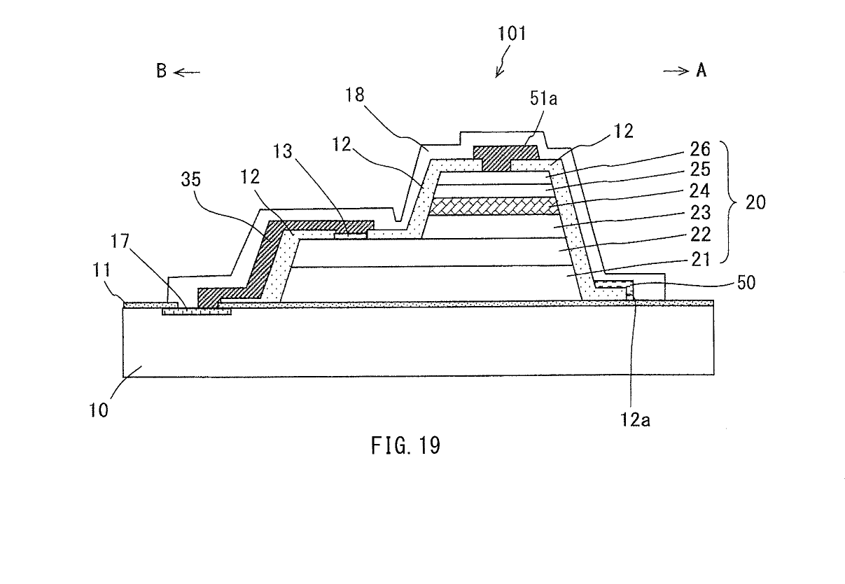

FIG. 18 is a schematic plan view of a main configuration of a semiconductor device 2 according to a sixth example embodiment of the invention. FIG. 19 is a schematic cross-sectional view, taken along line A-B of FIG. 18, of the semiconductor device 2 illustrated in FIG. 19. Note that the interlayer insulating film layer 11 and the passivation layer 18 are omitted in FIG. 18 for easier illustration.

The semiconductor device 2 differs from the semiconductor device 1 according to the foregoing fifth example embodiment illustrated in FIG. 15, primarily in that: a common electrode wiring line 51 has a shape different from that of the common electrode wiring line 32 in the fifth example embodiment; a light-shielding film 50 is newly provided; and a manufacturing method is different. Hence, elements in the semiconductor device 2 same as or equivalent to those of the semiconductor device 1 according to the fifth example embodiment described above are denoted with the same reference numerals to focus on a difference between the present example embodiment and the first example embodiment.

The common electrode wiring line 51 in this example embodiment may be configured by a connection section 51b, electrode sections 51a, and a pad connection section 51c. The connection section 51b may extend along each of the P-contact layers 26 of the LED lines on the insulating film 12. The electrode sections 51a each may extend perpendicularly from the connection section 51b to the P-contact layer 26 of one of the LEDs 20. The pad connection section 51c may extend perpendicularly from the connection section 51b to corresponding one of the common electrode pads 15 in a direction opposite to the electrode section 51a.

In this example embodiment, the connection section 51b does not cover the transverse direction end 12a of the insulating film 12. Instead, the newly provided light-shielding film 50 is so formed as to entirely cover both the upper part and the end of the transverse direction end 12a of the insulating film 12.

A description is given next of an example method of manufacturing the semiconductor device 2.

First, the interlayer insulating film layer 11 may be formed on the drive circuit substrate 10 excluding regions on the external connection pads 14, the common electrode pads 15, the individual electrode pads 16, and the openings 11a and 11b formed at the connection parts of the on-substrate wiring lines 17. The drive circuit substrate 10 may be provided with the drive circuit, and may include, on the surface, the external connection pads 14, the common electrode pads 15, the individual electrode pads 16, and the on-substrate wiring lines 17. Thereafter, the LEDs 20 in each of which no cathode electrode 13 is formed yet, may be disposed and subjected to joining at their predetermined locations on the interlayer insulating film layer 11.

Then, the insulating film 12 may be formed in the region that covers the LED lines as a whole and in the region that serves as the underlayer of the individual electrode wiring lines 35, excluding the predetermined locations on the surface of each of the LEDs 20 including the wiring line connection part that corresponds to the P-contact layer 26 and the wiring line connection part that corresponds to the cathode electrode 13 on the N-contact layer 22. Then, the cathode electrode 13 and the light-shielding film 50 may be formed in the same process step using the same material. Thereafter, the common electrode wiring line 51, the individual electrode wiring lines 35, and the connection wiring lines 36 may be formed, following which the passivation layer 18 as illustrated in FIG. 19 may be formed except for the surfaces of the respective external connection pads 14.

In the semiconductor device 2 having the foregoing example configuration, causing the drive current to flow across selected one of the common electrode pads 15 and selected one of the individual electrode pads 16 allows the designated one of the LEDs 20 to emit light. A part of the light emitted from the active layer 24 of that one of the LEDs 20 may be outputted to an upward part of the semiconductor device 2, whereas another part of the light may be propagated through the insulating film 12 to reach the region near the transverse direction end 12a of the insulating film 12 as illustrated in FIG. 17. Note that the multiple LEDs 20 may be selected together to allow each of the selected LEDs 20 to emit light.

The light having been propagated through the insulating film 12, however, is blocked and thus subjected to the light shielding by the light-shielding film 50 so formed as to cover the transverse direction end 12a of the insulating film 12. Hence, it is possible to prevent the leakage of light from the region near the transverse direction end 12a.

In the semiconductor device 2 according to this example embodiment, the light that propagates through the insulating film 12 is prevented from being reflected upward by a reflective structure such as, but not limited to, the connection wiring lines 40. Hence, it is possible to prevent a reduction in quality, resulting from a noise attributed to reflection light, of printing in a printer. Also, the light-shielding film 50 may be formed together with the cathode electrodes 13 in the same process step. This does not involve the necessity of newly providing a process step of forming the light-shielding film, making it possible to prevent a rise in costs.

### Seventh Example Embodiment

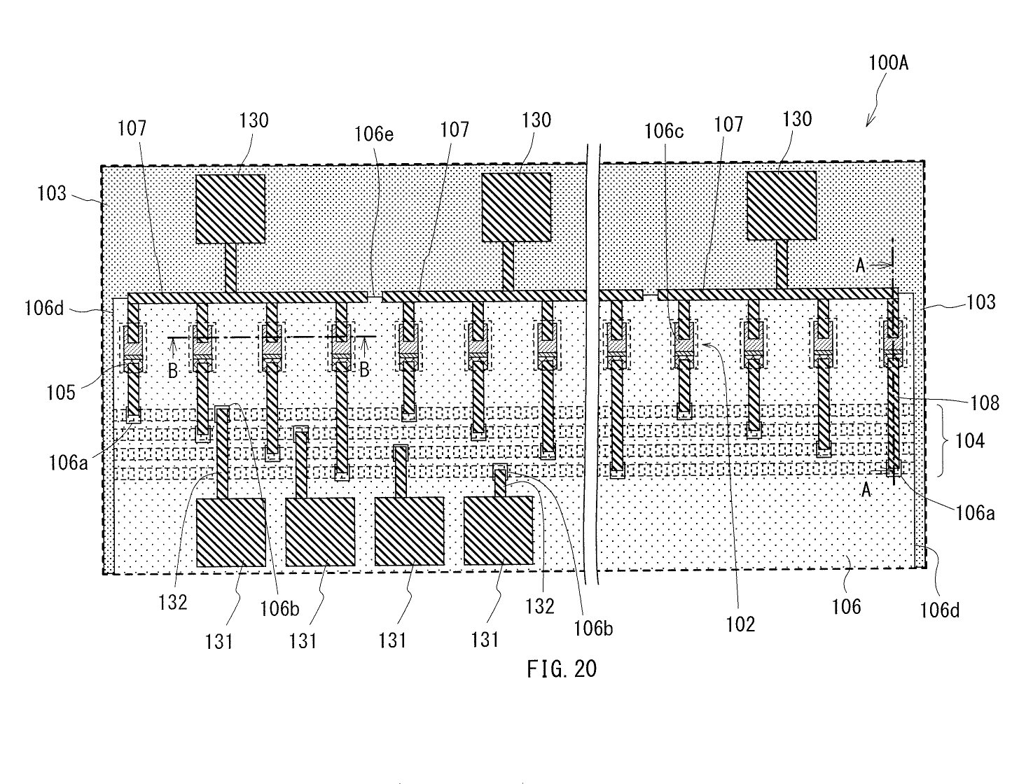

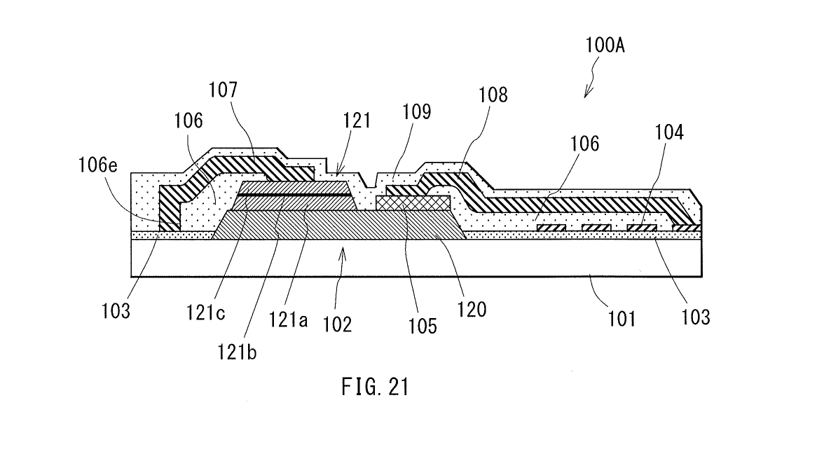

FIG. 20 is a schematic plan view of a main configuration of a semiconductor device 100A according to a seventh example embodiment of the invention. FIG. 21 is a schematic cross-sectional view, taken along line A-A of FIG. 20, of the semiconductor device 100A illustrated in FIG. 20. Note that the passivation film 109 is omitted in FIG. 20 for easier illustration.

The semiconductor device 100A is virtually similar in configuration to the semiconductor device 100 according to the foregoing first example embodiment, with the exception that a transverse direction end 106e of the organic insulating film 106 is provided between the LED lines of the LEDs 102 and a line of the common electrode pads 130, and that the transverse direction end 106e is covered with the common electrode wiring line 107.

In the semiconductor device 100A according to this example embodiment, the organic insulating film 106 includes the cliff 106d in addition to the transverse direction end 106e covered with the common electrode wiring line 107. Hence, it is possible for the semiconductor device 100A to prevent the light emitted from any LED 102 from being leaked, at a location different from a light-emitting region, in a direction that may reduce quality of printing.

### Eighth Example Embodiment

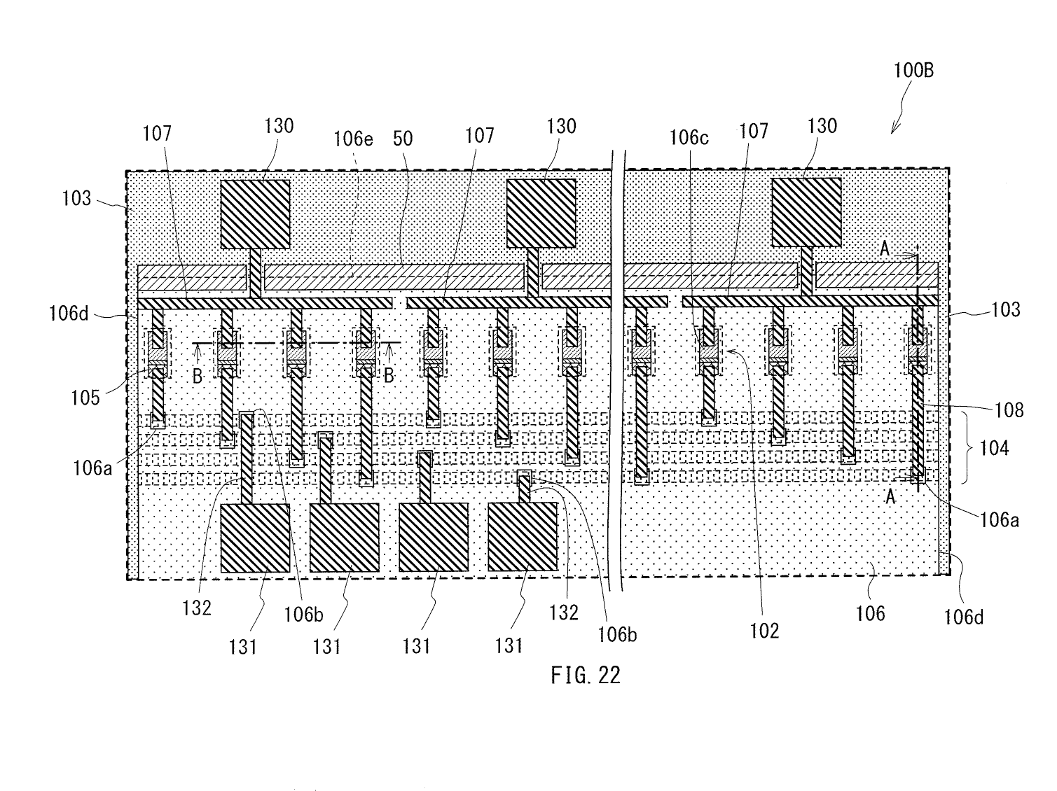

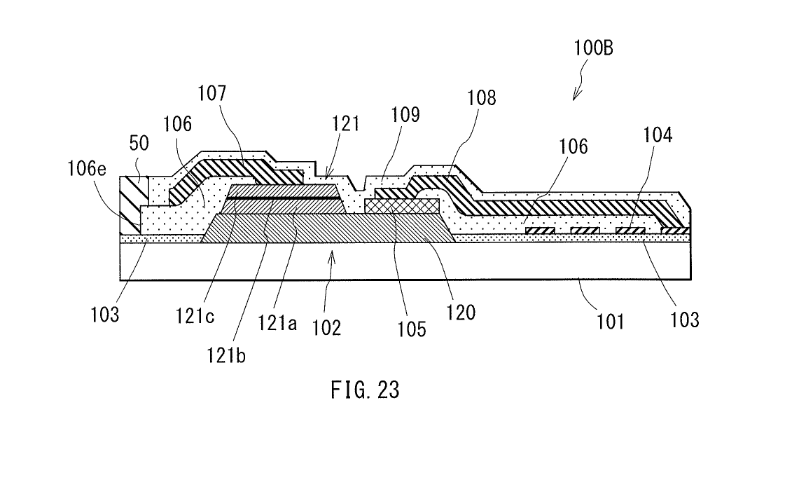

FIG. 22 is a schematic plan view of a main configuration of a semiconductor device 100B according to an eighth example embodiment of the invention. FIG. 23 is a schematic cross-sectional view, taken along line A-A of FIG. 22, of the semiconductor device 100B illustrated in FIG. 22. Note that the passivation film 109 is omitted in FIG. 22 for easier illustration.

The semiconductor device 100B is virtually similar in configuration to the semiconductor device 100A according to the foregoing seventh example embodiment, with the exception that a light-shielding film 150 is newly added. As with the semiconductor device 100A, the semiconductor device 100B may include the transverse direction end 106e of the organic insulating film 106 between the LED lines of the LEDs 102 and the line of the common electrode pads 130. The transverse direction end 106e, however, is covered with the light-shielding film 150 instead of the common electrode wiring line 107. The light-shielding film 150 may be so formed as to entirely cover both an upper part and an end of the transverse direction end 106e of the organic insulating film 106.

In the semiconductor device 100B according to this example embodiment, the organic insulating film 106 includes the cliff 106d in addition to the transverse direction end 106e covered with the light-shielding film 150. Hence, it is possible for the semiconductor device 100B as well to prevent the light emitted from any LED 102 from being leaked, at a location different from a light-emitting region, in a direction that may reduce quality of printing.

### Ninth Example Embodiment

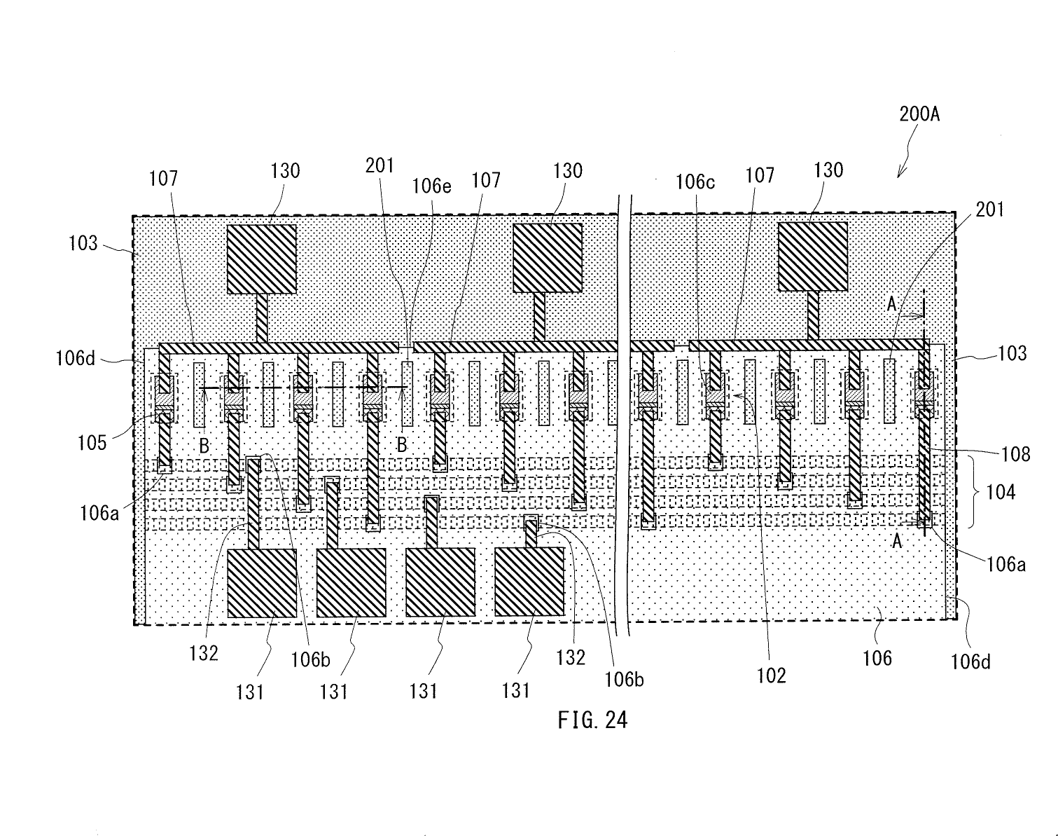

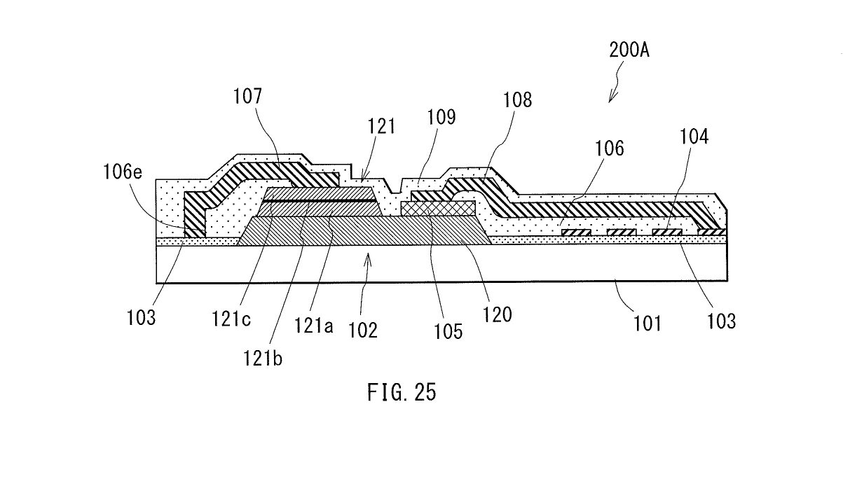

FIG. 24 is a schematic plan view of a main configuration of a semiconductor device 200A according to a ninth example embodiment of the invention. FIG. 25 is a schematic cross-sectional view, taken along line A-A of FIG. 24, of the semiconductor device 200A illustrated in FIG. 24. Note that the passivation film 109 is omitted in FIG. 24 for easier illustration.

The semiconductor device 200A is virtually similar in configuration to the semiconductor device 200 according to the foregoing second example embodiment, with the exception that the transverse direction end 106e of the organic insulating film 106 is provided between the LED lines of the LEDs 102 and the line of the common electrode pads 130, and that the transverse direction end 106e is covered with the common electrode wiring line 107.

In the semiconductor device 200A according to this example embodiment, the organic insulating film 106 includes the cliffs 106d and 106f in addition to the transverse direction end 106e covered with the common electrode wiring line 107. Hence, it is possible for the semiconductor device 200A as well to prevent the light emitted from any LED 102 from being leaked, at a location different from a light-emitting region, in a direction that may reduce quality of printing.

### Tenth Example Embodiment

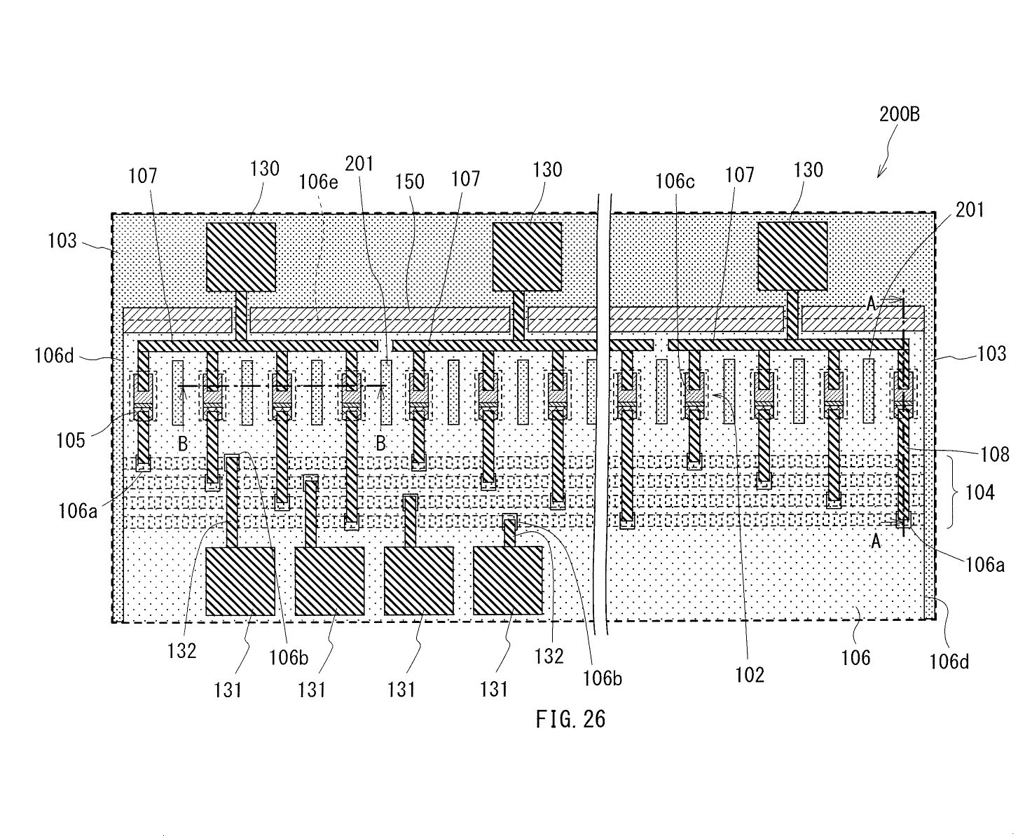

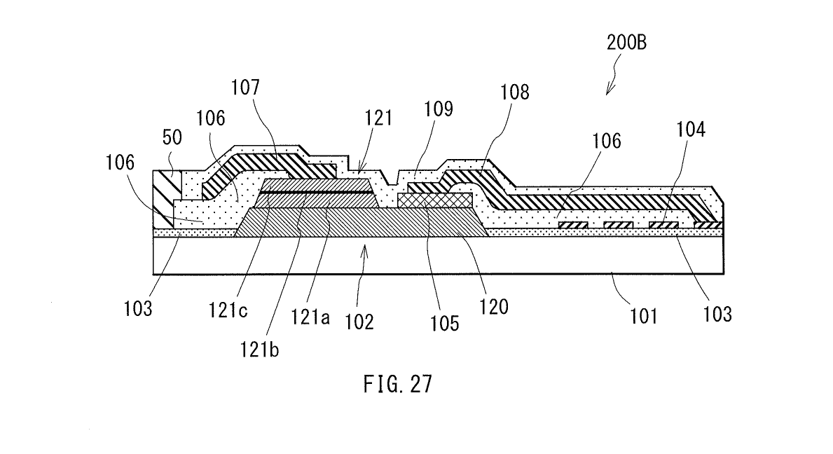

FIG. 26 is a schematic plan view of a main configuration of a semiconductor device 200B according to a tenth example embodiment of the invention. FIG. 27 is a schematic cross-sectional view, taken along line A-A of FIG. 26, of the semiconductor device 200B illustrated in FIG. 26. Note that the passivation film 109 is omitted in FIG. 26 for easier illustration.

The semiconductor device 200B is virtually similar in configuration to the semiconductor device 200A according to the foregoing ninth example embodiment, with the exception that the light-shielding film 150 is newly added. As with the semiconductor device 200A, the semiconductor device 200B may include the transverse direction end 106e of the organic insulating film 106 between the LED lines of the LEDs 102 and the line of the common electrode pads 130. The transverse direction end 106e, however, is covered with the light-shielding film 150 instead of the common electrode wiring line 107. The light-shielding film 150 may be so formed as to entirely cover both the upper part and the end of the transverse direction end 106e of the organic insulating film 106.

In the semiconductor device 200B according to this example embodiment, the organic insulating film 106 includes the cliffs 106d and 106f in addition to the transverse direction end 106e covered with the light-shielding film 150. Hence, it is possible for the semiconductor device 100B as well to prevent the light emitted from any LED 102 from being leaked, at a location different from a light-emitting region, in a direction that may reduce quality of printing.

### Eleventh Example Embodiment

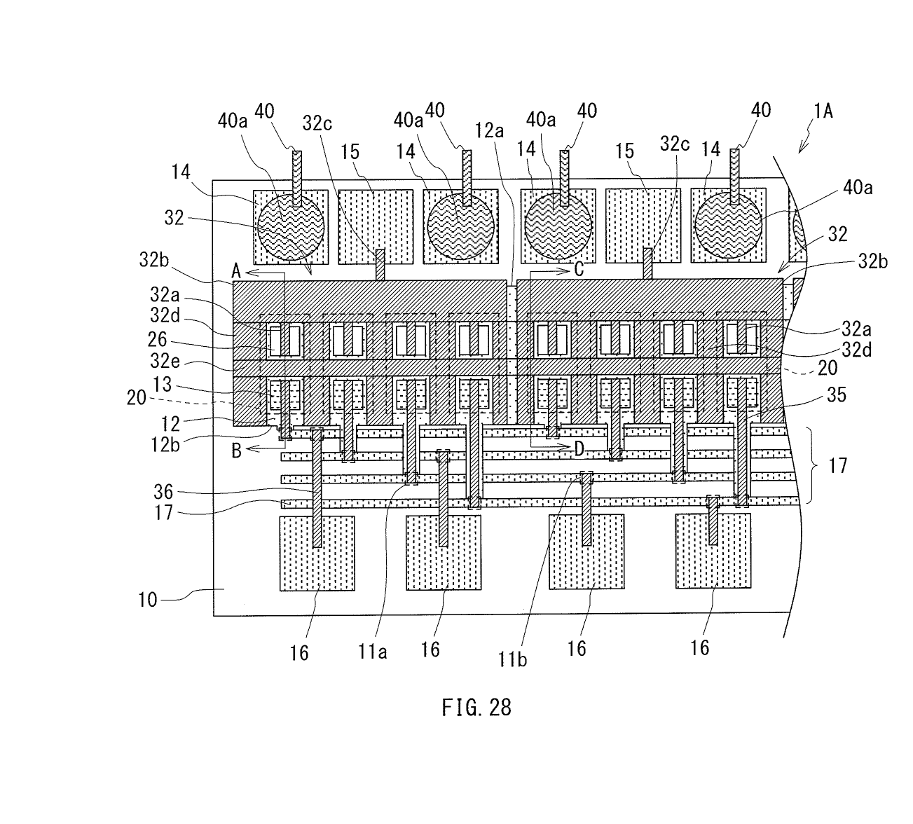

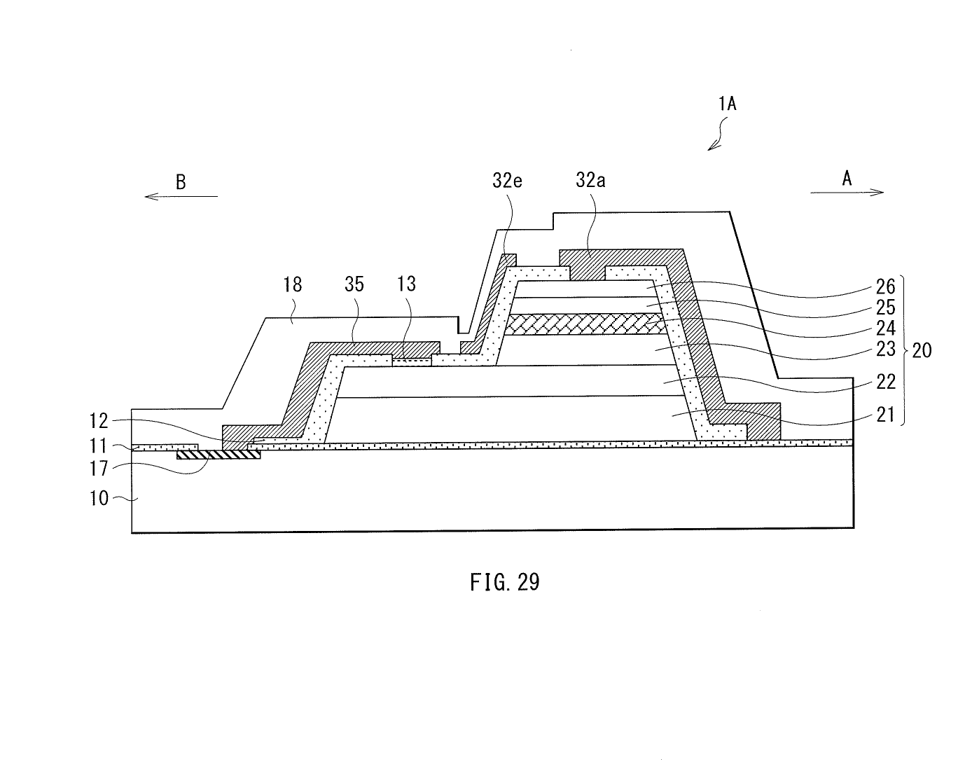

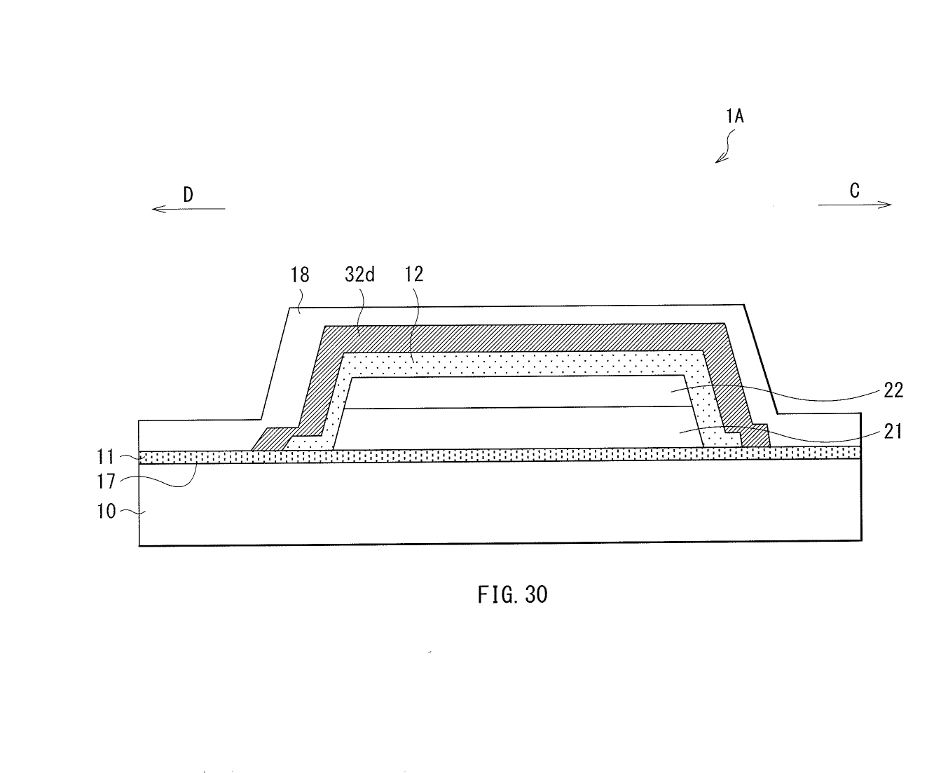

FIG. 28 is a schematic plan view of a main configuration of a semiconductor device 1A according to an eleventh example embodiment of the invention. FIG. 29 is a schematic cross-sectional view, taken along line A-B of FIG. 28, of the semiconductor device 1A illustrated in FIG. 28. FIG. 30 is a schematic cross-sectional view, taken along line C-D of FIG. 28, of the semiconductor device 1A illustrated in FIG. 28. Note that the interlayer insulating film layer 11 and the passivation layer 18 are omitted in FIG. 28 for easier illustration.

The semiconductor device 1A is virtually similar in configuration to the semiconductor device 1 according to the foregoing fifth example embodiment, with the exception that the shielding connection section 32b extends to a region that is overlapped with a part of one or more of the LEDs 20, and that the common electrode wiring line 32 newly includes extension sections 32d and 32e. The extension sections 32d each may have a first end coupled to the shielding connection section 32b and so extending away from the shielding connection section 32b as to be overlapped with a partial region of one or more of the LEDs 20. The extension sections 32d each may also have a second end so provided as to cover a transverse direction end 12b located on opposite side of the transverse direction end 12a of the insulating film 12. The extension section 32e may so extend, in the array direction of the LEDs 20 through a region between the electrode sections 32a and the individual electrode wiring lines 35, as to couple together the plurality of extension sections 32d arranged in the array direction of the LEDs 20.

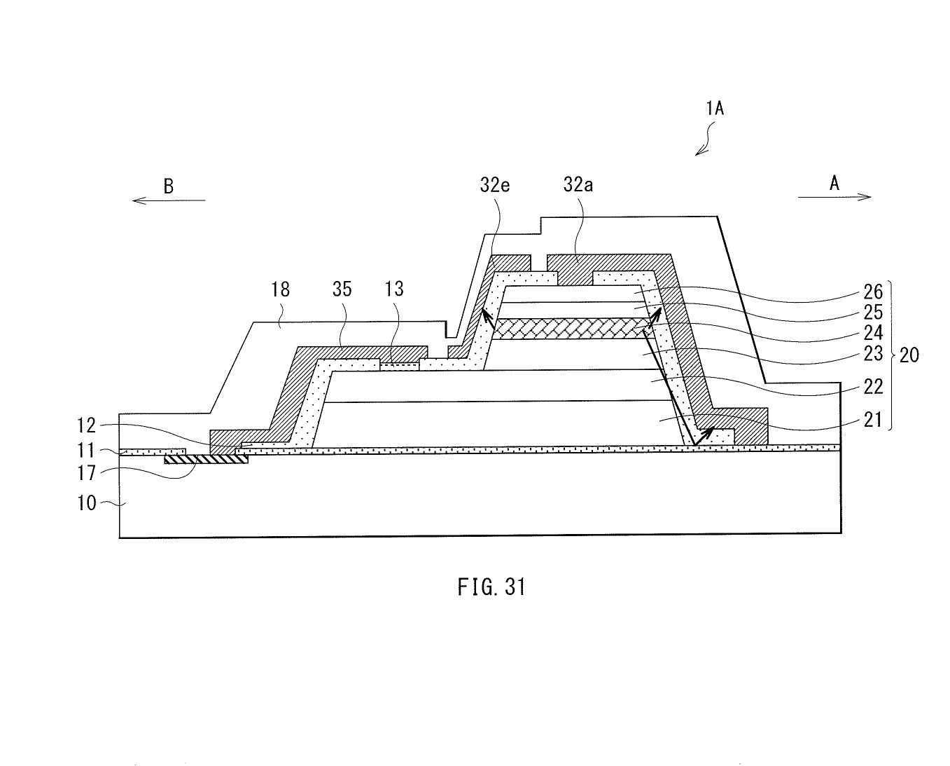

In the semiconductor device 1A having the foregoing example configuration, a part of the light emitted from the active layer 24 may be outputted to an upward part of the semiconductor device 1A, whereas another part of the light may be propagated through the insulating film 12 as illustrated by arrows in FIG. 31 to reach regions near the transverse direction ends 12a and 12b of the insulating film 12 and a region around any of the LEDs 20. The light having been propagated through the insulating film 12, however, is blocked and thus subjected to the light shielding by the shielding connection section 32b of the common electrode wiring line 32 which may be so formed as to cover the transverse direction ends 12a and 12b and the regions around the LEDs 20. Hence, it is possible to prevent the leakage of light from the regions near the transverse direction ends 12a and 12b and the regions around the LEDs 20.

### Twelfth Example Embodiment

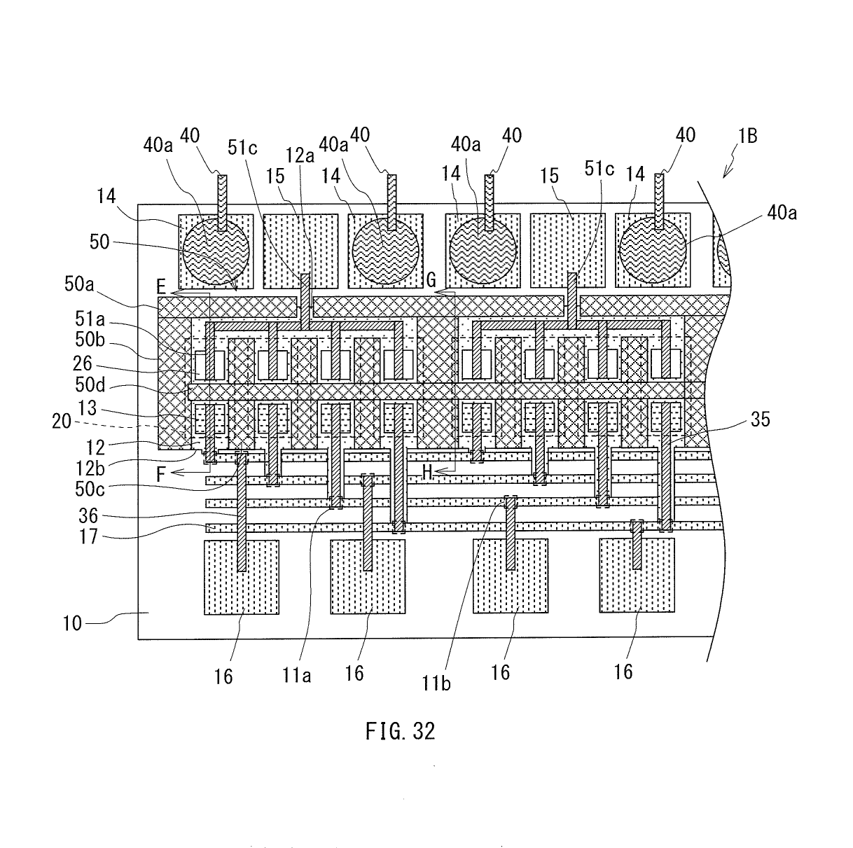

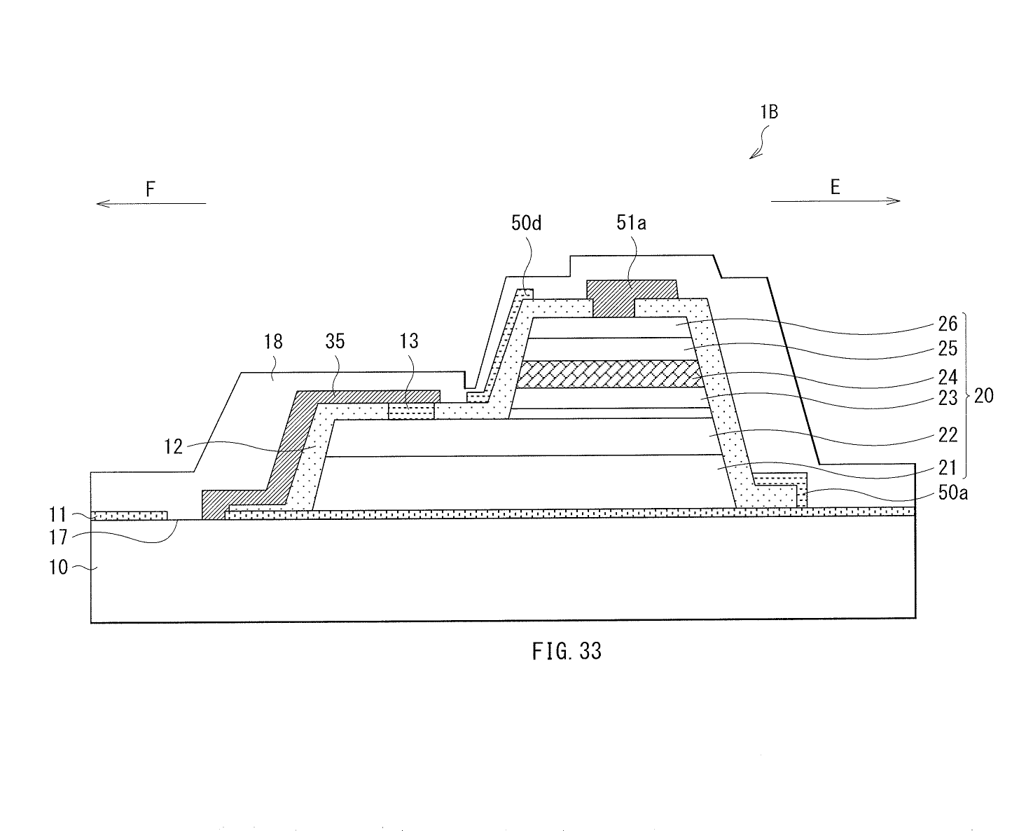

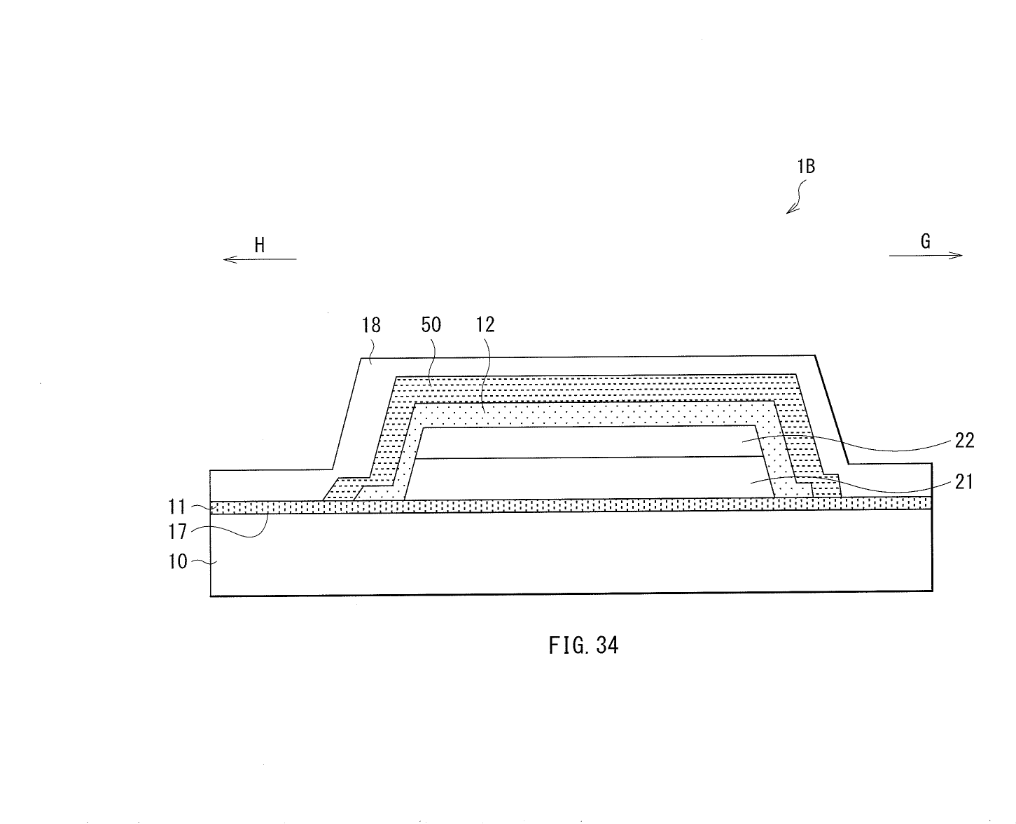

FIG. 32 is a schematic plan view of a main configuration of a semiconductor device 1B according to a twelfth example embodiment of the invention. FIG. 33 is a schematic cross-sectional view, taken along line E-F of FIG. 32, of the semiconductor device 1B illustrated in FIG. 32. FIG. 34 is a schematic cross-sectional view, taken along line G-H of FIG. 32, of the semiconductor device 1B illustrated in FIG. 32. Note that the interlayer insulating film layer 11 and the passivation layer 18 are omitted in FIG. 32 for easier illustration.

The semiconductor device 1B is virtually similar in configuration to the semiconductor device 2 according to the foregoing sixth example embodiment, with the exception that the light-shielding film 50 extends to a region that is overlapped with a part of one or more of the LEDs 20, and that a part of the light-shielding film 50 is so provided as to cover the transverse direction end 12b located on the opposite side of the transverse direction end 12a of the insulating film 12 as well. The light-shielding film 50 may include a first section 50a, second sections 50b, third sections 50c, and a fourth section 50d. The first section 50a may so extend in the array direction of the LEDs 20 as to cover the transverse direction end 12a. The second sections 50b each may have a first end coupled to the first section 50a and so extending, in a direction orthogonal to the array direction of the LEDs 20, away from the first section 50a as to be overlapped with a partial region of one or more of the LEDs 20. The second sections 50b each may also have a second end so provided as to cover the transverse direction end 12b located on the opposite side of the transverse direction end 12a of the insulating film 12. The third sections 50c each may be so provided as to fill a gap between the LEDs 20 in a region between one second section 50b and another second section 50b which are adjacent to each other. The fourth section 50d may so extend, in the array direction of the LEDs 20 through a region between the electrode sections 51a and the individual electrode wiring lines 35, as to intersect with the second and the third sections 50b and 50c which are arranged in the array direction of the LEDs 20.

In the semiconductor device 1B having the foregoing example configuration, a part of the light emitted from the active layer 24 may be propagated through the insulating film 12 to reach the regions near the transverse direction ends 12a and 12b of the insulating film 12 and the region around any of the LEDs 20. The light having been propagated through the insulating film 12, however, is blocked and thus subjected to the light shielding by the light-shielding film 50. Hence, it is possible to prevent the leakage of light from the regions near the transverse direction ends 12a and 12b and the regions around the LEDs 20.

### Thirteenth Example Embodiment

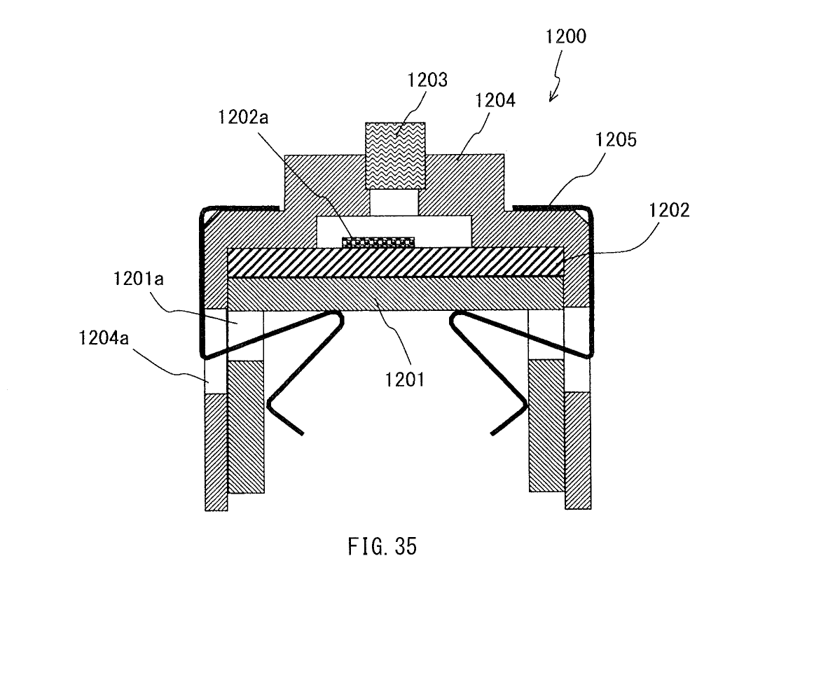

FIG. 35 illustrates an LED print head 1200 according to a thirteenth example embodiment of the invention. The LED head 1200 corresponds to a specific but non-limiting example of an “LED head” according to an embodiment of the invention.

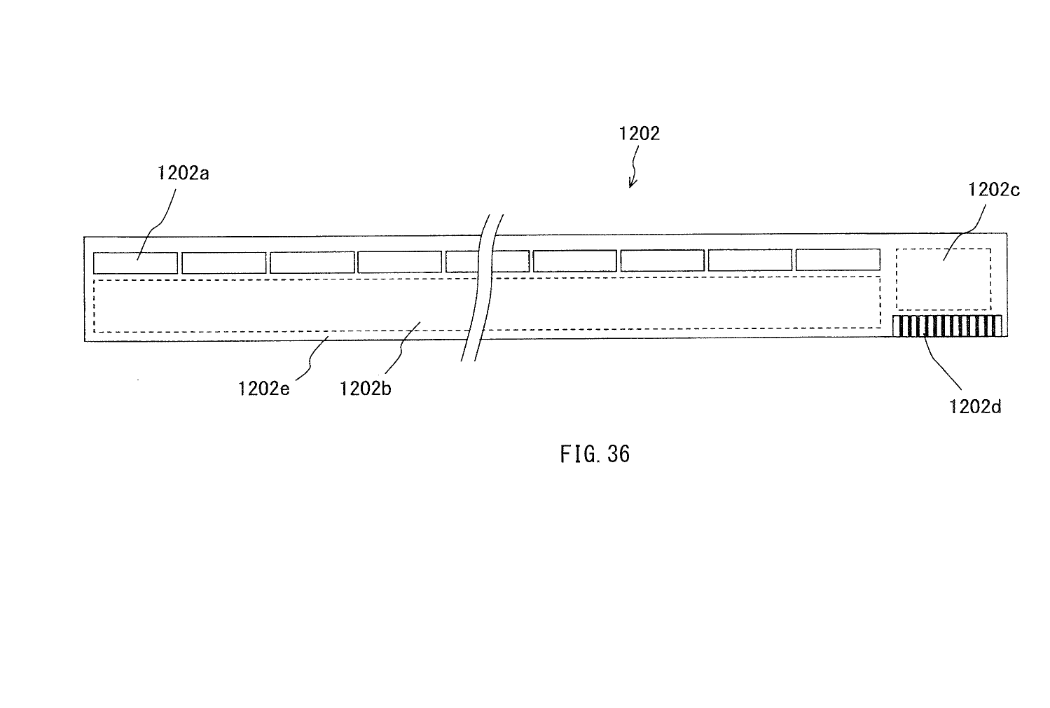

Referring to FIG. 35, an LED unit 1202 may be mounted on a base member 1201. The LED unit 1202 may have a configuration in which the semiconductor device according to any of the first example embodiment to the twelfth example embodiment is mounted on a mounting board. FIG. 36 is a plan view of an arrangement according to an example configuration of the LED unit 1202. Referring to FIG. 36, a plurality of semiconductor devices according to any of the foregoing example embodiments may be disposed as light-emitting units 1202a in a longitudinal direction on a mounting board 1202e. Besides the light-emitting units 1202a, the mounting board 1202e may have areas 1202b and 1202c, a connector 1202d, and any other area and element. The areas 1202b and 1202c may be areas in which electronic components that drive and control the light-emitting units 1202a are disposed and wiring lines are formed, i.e., areas directed to electronic component mounting, wiring, and connection. The connector 1202d may supply control signals and electric power from outside.

A rod lens array 1203 may be provided at an upper part of light-emitting sections of the respective light-emitting units 1202a. The rod lens array 1203 may serve as a non-limiting example of an optical element, and may collect light emitted from those light-emitting sections. The rod lens array 1203 may have a configuration in which a plurality of columnar optical lenses are arrayed along the linearly-arranged light-emitting sections (e.g., the array of the LEDs 102 illustrated in FIG. 1) of the respective light-emitting units 1202a. The rod lens array 1203 may be held at a predetermined position by a lens holder 1204 that may serve as a non-limiting example of an optical element holder.

The lens holder 1204 may be so formed as to cover a base member 1201 and the LED unit 1202 as illustrated in FIG. 35. The base member 1201, the LED unit 1202, and the lens holder 1204 may be integrally held in an interposed fashion by dampers 1205. The dampers 1205 each may be disposed through openings 1201a and 1204a formed respectively on the base member 1201 and the lens holder 1204. With this configuration, the light generated by the LED unit 1202 may be applied to a predetermined external member through the rod lens array 1203. The LED print head 1200 may be used for an exposure unit directed to, for example but not limited to, an electrophotographic printer, an electrophotographic copying machine, or any other electrophotographic instrument.

The LED print head 1200 according to the foregoing example embodiment employs, as the light-emitting units 1202a, the semiconductor device according to any of the first example embodiment to the twelfth example embodiment described above. Hence, it is possible to provide the LED print head 1200 having excellent durability and high accuracy.

### Fourteenth Example Embodiment

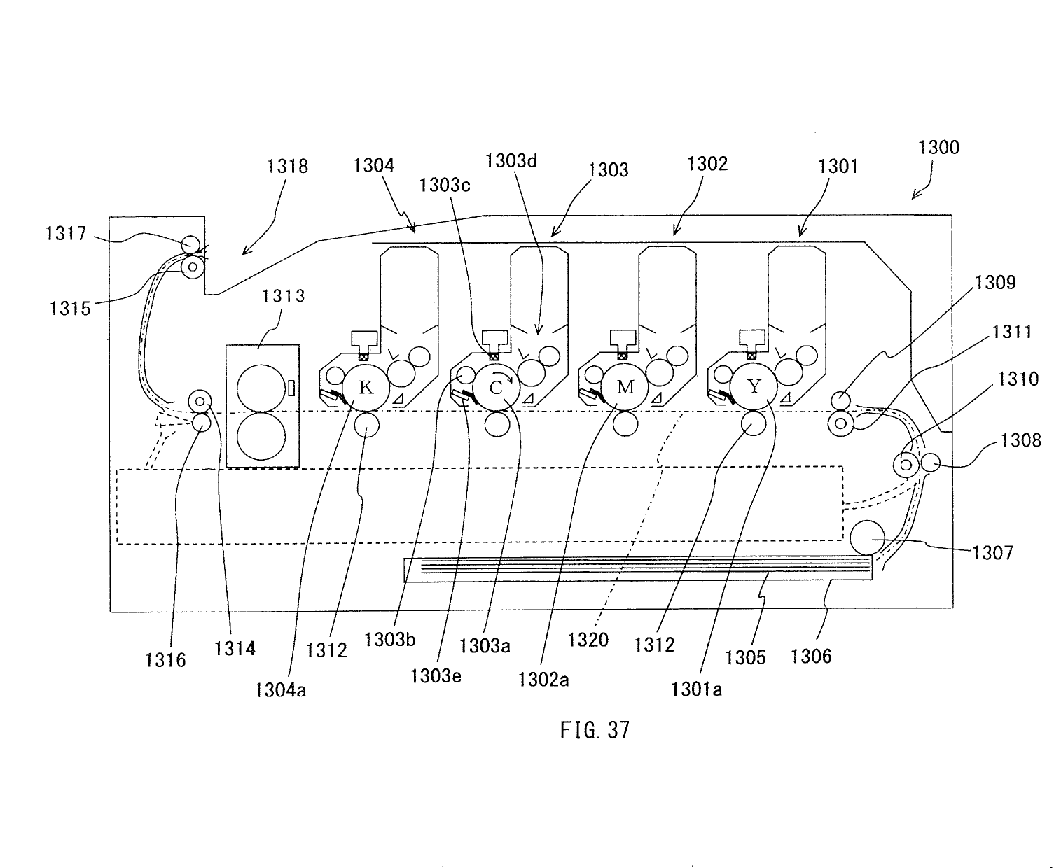

FIG. 37 schematically illustrates a main configuration of an image forming apparatus 1300 according to a fourteenth example embodiment of the invention. The image forming apparatus 1300 corresponds to a specific but non-limiting example of an “image forming apparatus” according to an embodiment of the invention.

Referring to FIG. 37, the image forming apparatus 1300 may include therein four process units 1301, 1302, 1303, and 1304 that may be provided along a conveying path 1320 of a recording medium 1305 in order from upstream side of the conveying path 1320. The process units 1301 to 1304 may respectively form a yellow image, a magenta image, a cyan image, and a black image. These process units 1301 to 1304 may have the same internal configuration as each other; hence, a description is given with reference to an example of the cyan process unit 1303 to describe the internal configurations of the process units 1301 to 1304.

The process unit 1303 may include a photosensitive drum 1303a that serves as an image supporting member. The photosensitive drum 1303a may be disposed rotatably in a direction denoted by an arrow. A charging unit 1303b and an exposure unit 1303c may be disposed at a surrounding part of the photosensitive drum 1303a, and may be provided in order from upstream side in a direction of rotation of the photosensitive drum 1303a. The charging unit 1303b may supply a surface of the photosensitive drum 1303a with electric power to charge the surface of the photosensitive drum 1303a. The exposure unit 1303c may selectively irradiate the charged surface of the photosensitive drum 1303a with light to form an electrostatic latent image. The surrounding part of the photosensitive drum 1303a may be further provided with a developing unit 1303d and a cleaning unit 1303e. The developing unit 1303d may attach a toner having a predetermined color (cyan in this case) onto the surface of the photosensitive drum 1303a on which the electrostatic latent image is formed to form a developed image. The cleaning unit 1303e may remove the toner remaining on the surface of the photosensitive drum 1303a. The drum or a roller used in each of those units may be rotated by unillustrated drive source and gears.

The image forming apparatus 1300 may include a medium cassette (paper cassette) 1306 and a hopping roller 1307. The medium cassette 1306 may be attached at a lower part of the image forming apparatus 1300, and store the recording medium 1305 in a stacked fashion. The recording medium 1305 may be, for example but not limited to, paper. The hopping roller 1307 may be provided above the medium cassette 1306, and adapted to convey the recording medium 1305 one by one in a separated fashion. Downstream of the hopping roller 1307 in the conveying direction of the recording medium 1305 may be pinch rollers 1308 and 1309 and resist rollers 1310 and 1311. The resist rollers 1310 and 1311 each may pinch the recording medium 1305 in conjunction with corresponding one of the pinch rollers 1308 and 1309 to convey the recording medium 1305 to the process units 1301 to 1304 while correcting a skew of the recording medium 1305. The hopping roller 1307 and the resist rollers 1310 and 1311 may be rotated in tandem by unillustrated drive source and gears.

Transfer rollers 1312 each may be disposed at a position that faces corresponding one of the photosensitive drums of the respective process units 1301 to 1304. Each of the transfer rollers 1312 may be made of a semi-conductive rubber or any other suitable material. The photosensitive drums 1301a to 1304a and the transfer rollers 1312 may be so configured that predetermined potentials are generated between the surfaces of the photosensitive drums 1301a to 1304a and surfaces of the transfer rollers 1312 to allow the toners on the respective photosensitive drums 1301a to 1304a to be transferred onto the recording medium 1305.

A fixing unit 1313 may include a heating roller and a backup roller, and may apply pressure and heat to the toners having been transferred onto the recording medium 1305 to fix the toners thereto. Discharge rollers 1314 and 1315 each may pinch the recording medium 1305 fed from the fixing unit 1313 in conjunction with corresponding one of pinch rollers 1316 and 1317 provided in a discharge section to convey the recording medium 1305 to a recording medium stacker 1318. The discharge rollers 1314 and 1315 may be rotated in tandem by unillustrated drive source and gears. The LED print head 1200 described in the thirteenth example embodiment may be employed in the exposure unit 1303c used in the image forming apparatus 1300.

Next, a description is given of an operation of the image forming apparatus 1300 having the foregoing configuration. The recording medium 1305 stored in a stacked fashion in the medium cassette 1306 may be conveyed one by one from the top in a separated fashion by the hopping roller 1307. The recording medium 1305 fed from the medium cassette 1306 may then be pinched by the resist rollers 1310 and 1311 and the pinch rollers 1308 and 1309 to be conveyed to the photosensitive drum 1301a of the process unit 1301 and the transfer roller 1312. The recording medium 1305 may then be pinched by the photosensitive drum 1301a and the transfer roller 1212, causing a toner image to be transferred onto a recording surface of the recording medium 1305 while conveying the recording medium 1305 by means of the rotation of the photosensitive drum 1301a.

Likewise, the recording medium 1305 may pass through the process units 1302 to 1304 sequentially. During the course of passing through the process units 1301 to 1304, the toner images of respective colors may be overlaid onto the recording surface of the recording medium 1305 to be transferred onto the recording surface sequentially. The toner images of the respective colors here may be obtained as a result of development performed by the developing units 1301d to 1304d of the electrostatic latent images formed by the respective exposure units 1301c to 1304c. The recording medium 1305, to which the toner images have been fixed by the fixing unit 1313, may be pinched by the discharge rollers 1314 and 1315 and the pinch rollers 1316 and 1317 to be discharged to the recording medium stacker 1318 located outside of the image forming apparatus 1300. A color image may thus be formed on the recording medium 1305 following an example process described above.

The image forming apparatus 1300 according to the foregoing example embodiment employs the LED print head 1200 according to the thirteenth example embodiments described above. Hence, it is possible to provide the image forming apparatus 1300 that has excellent durability and high reliability, and makes it possible to prevent degradation in printing quality attributed to optical noise and thereby to perform printing of high quality.

As used herein and in the following appended claims, terms “up” and “down” and their respective equivalents (including “upper” and “lower” and “upward” and “downward” without limitation) are used for convenience purpose only, and are not intended to limit an absolute positional relationship of elements in arrangement of such elements.

Also, a description has been given of the example embodiments and the modification examples with reference to the color printer as a specific but non-limiting example of the “image forming apparatus”. However, the term “image forming apparatus” is not limited thereto. Any of the example embodiments and the modification examples described above is applicable to a monochrome printer, a copying machine, a facsimile, a multi-function peripheral in which two or more of the printer, the copying machine, and the facsimile are combined, or any other instrument that forms an image on a medium.

Furthermore, the invention encompasses any possible combination of some or all of the various embodiments and the modification examples described herein and incorporated herein.

It is possible to achieve at least the following configurations from the above-described example embodiments of the invention.

(1) A semiconductor device, including:

a substrate;

a plurality of light-emitting elements disposed linearly at a predetermined interval on the substrate;

an insulating film provided on the substrate and having openings that correspond to the respective light-emitting elements, the insulating film having an end, the end being provided in an array direction of the light-emitting elements and having a first cliff, the first cliff having a face that makes one of a right angle and an acute angle to a surface of the substrate; and

a wiring line provided on the insulating film and coupled to each of the light-emitting elements.

(2) The semiconductor device according to (1), further including a first slit extending in a direction orthogonal to the array direction of the light-emitting elements and provided between the light-emitting elements that are adjacent to each other, and having a second cliff, the second cliff having a face that makes one of a right angle and an acute angle to the surface of the substrate.
(3) The semiconductor device according to (1), further including:

an on-substrate wiring line provided between the substrate and the insulating film, and extending in the array direction of the light-emitting elements; and

a second slit extending in the array direction of the light-emitting elements and provided on the insulating film between one or more of the light-emitting elements and the on-substrate wiring line, and having a third cliff, the third cliff having a face that makes one of a right angle and an acute angle to the surface of the substrate.

(4) The semiconductor device according to (1), further including a planarizing film provided on the substrate and on which the light-emitting elements are provided, and having a fourth cliff, the fourth cliff having a face that makes one of a right angle and an acute angle to the surface of the substrate.
(5) The semiconductor device according to (1), further including a passivation film that covers the insulating film and the wiring line.
(6) The semiconductor device according to (1), wherein the insulating film includes a light-transmitting film configured to allow light emitted from the light-emitting elements to be transmitted therethrough.
(7) An LED head, including a plurality of the semiconductor devices according to any one of (1) to (6).
(8) An image forming apparatus, including the LED head according to (7).
(9) The semiconductor device according to (1), wherein a part of the wiring line has a width that corresponds at least to one or more of the light-emitting elements, and thereby extends to cover, in the array direction of the light-emitting elements, the end of the insulating film which extends in the array direction of the light-emitting elements.
(10) The semiconductor device according to (1), further including a light-shielding film having a width that corresponds at least to one or more of the light-emitting elements, and thereby extending to cover, in the array direction of the light-emitting elements, the end of the insulating film which extends in the array direction of the light-emitting elements.
(11) A semiconductor device, including:

a substrate;

a plurality of light-emitting elements disposed on the substrate;

an insulating film provided in a region on the substrate and having openings that face the respective light-emitting elements, the insulating film having an end that extends in an array direction of the light-emitting elements, the region including the light-emitting elements; and

a light-shielding film that extends to cover the end of the insulating film.

(12) The semiconductor device according to (11), further including a wiring line that includes the light-shielding film and electrically coupled to the light-emitting elements, wherein the light-shielding film has a width that corresponds at least to one or more of the light-emitting elements, and thereby extends to cover, in the array direction of the light-emitting elements, the end of the insulating film.
(13) The semiconductor device according to (11), wherein the light-shielding film includes a metal.
(14) The semiconductor device according to (13), the metal includes a material that is same as a material of an electrode formed in one or more of the light-emitting elements.
(15) The semiconductor device according to (11), wherein the insulating film allows light of a wavelength, corresponding to a wavelength of light emitted from one or more of the light-emitting elements, to be transmitted therethrough.
(16) The semiconductor device according to (11), wherein the insulating film includes an organic film.
(17) The semiconductor device according to (11), wherein the insulating film includes an inorganic film.
(18) The semiconductor device according to (11), wherein the light-shielding film has a length that corresponds to one or more of the light-emitting elements and extends in a direction orthogonal to the array direction of the light-emitting elements, and covers both ends including the end of the insulating film.
(19) The semiconductor device according to (18), wherein the light-shielding film occupies a part of a region that is overlapped with one or more of the light-emitting elements.
(20) An LED head, including a plurality of the semiconductor devices according to any one of (11) to (19).
(21) An image forming apparatus, including the LED head according to (20).

Although the invention has been described in terms of exemplary embodiments, it is not limited thereto. It should be appreciated that variations may be made in the described embodiments by persons skilled in the art without departing from the scope of the invention as defined by the following claims. The limitations in the claims are to be interpreted broadly based on the language employed in the claims and not limited to examples described in this specification or during the prosecution of the application, and the examples are to be construed as non-exclusive. For example, in this disclosure, the term “preferably”, “preferred” or the like is non-exclusive and means “preferably”, but not limited to. The use of the terms first, second, etc. do not denote any order or importance, but rather the terms first, second, etc. are used to distinguish one element from another. The term “substantially” and its variations are defined as being largely but not necessarily wholly what is specified as understood by one of ordinary skill in the art. The term “about” or “approximately” as used herein can allow for a degree of variability in a value or range. Moreover, no element or component in this disclosure is intended to be dedicated to the public regardless of whether the element or component is explicitly recited in the following claims.

What is claimed is:

1. A semiconductor device, comprising:
a substrate;
a plurality of light-emitting elements disposed linearly at a predetermined interval on the substrate;
an insulating film provided on the substrate and having openings that correspond to the respective light-emitting elements, the insulating film having an end, the end being provided in an array direction of the light-emitting elements and having a first cliff, the first cliff having a face that makes one of a right angle and an acute angle to a surface of the substrate; and
a wiring line provided on the insulating film and coupled to each of the light-emitting elements.

2. The semiconductor device according to claim 1, further comprising a first slit extending in a direction orthogonal to the array direction of the light-emitting elements and provided between the light-emitting elements that are adjacent to each other, and having a second cliff, the second cliff having a face that makes one of a right angle and an acute angle to the surface of the substrate.

3. The semiconductor device according to claim 1, further comprising:
an on-substrate wiring line provided between the substrate and the insulating film, and extending in the array direction of the light-emitting elements; and
a second slit extending in the array direction of the light-emitting elements and provided on the insulating film between one or more of the light-emitting elements and the on-substrate wiring line, and having a third cliff, the third cliff having a face that makes one of a right angle and an acute angle to the surface of the substrate.

4. The semiconductor device according to claim 1, further comprising a planarizing film provided on the substrate and on which the light-emitting elements are provided, and having a fourth cliff, the fourth cliff having a face that makes one of a right angle and an acute angle to the surface of the substrate.

5. The semiconductor device according to claim 1, wherein the insulating film comprises a light-transmitting film configured to allow light emitted from the light-emitting elements to be transmitted therethrough.

6. An LED head, comprising a plurality of the semiconductor devices according to claim 1.

7. An image forming apparatus, comprising the LED head according to claim 6.

8. The semiconductor device according to claim 1, wherein a part of the wiring line has a width that corresponds at least to one or more of the light-emitting elements, and thereby extends to cover, in the array direction of the light-emitting elements, the end of the insulating film which extends in the array direction of the light-emitting elements.

9. The semiconductor device according to claim 1, further comprising a light-shielding film having a width that corresponds at least to one or more of the light-emitting elements, and thereby extending to cover, in the array direction of the light-emitting elements, the end of the insulating film which extends in the array direction of the light-emitting elements.

10. A semiconductor device, comprising:
a substrate;
a plurality of light-emitting elements disposed on the substrate;
an insulating film provided in a region on the substrate and having openings that face the respective light-emitting elements, the insulating film having an end that extends in an array direction of the light-emitting elements, the region including the light-emitting elements; and
a light-shielding film that extends to cover the end of the insulating film.

11. The semiconductor device according to claim 10, further comprising a wiring line that comprises the light-shielding film and electrically coupled to the light-emitting elements,
wherein the light-shielding film has a width that corresponds at least to one or more of the light-emitting elements, and thereby extends to cover, in the array direction of the light-emitting elements, the end of the insulating film.

12. The semiconductor device according to claim 10, wherein the light-shielding film comprises a metal.

13. The semiconductor device according to claim 12, the metal comprises a material that is same as a material of an electrode formed in one or more of the light-emitting elements.

14. The semiconductor device according to claim 10, wherein the insulating film allows light of a wavelength, corresponding to a wavelength of light emitted from one or more of the light-emitting elements, to be transmitted therethrough.

15. The semiconductor device according to claim 10, wherein the insulating film comprises an organic film.

16. The semiconductor device according to claim 10, wherein the insulating film comprises an inorganic film.

17. The semiconductor device according to claim 10, wherein the light-shielding film has a length that corresponds to one or more of the light-emitting elements and extends in a direction orthogonal to the array direction of the light-emitting elements, and covers both ends including the end of the insulating film.

18. The semiconductor device according to claim 17, wherein the light-shielding film occupies a part of a region that is overlapped with one or more of the light-emitting elements.

19. An LED head, comprising a plurality of the semiconductor devices according to claim 10.

20. An image forming apparatus, comprising the LED head according to claim 19.
